(19) United States
(12) Patent Application Publication
(10) Pub. No.: US 2023/0317606 A1
(43) Pub. Date: Oct. 5, 2023

(54) SEMICONDUCTOR DEVICE

(71) Applicant: Samsung Electronics Co., Ltd., Suwon-si (KR)

(72) Inventors: Yejeong SEO, Suwon-si (KR); Hyuk KIM, Suwon-si (KR)

(73) Assignee: Samsung Electronics Co., Ltd., Suwon-si (KR)

(21) Appl. No.: 17/970,008

(22) Filed: Oct. 20, 2022

(30) Foreign Application Priority Data
Mar. 29, 2022 (KR) 10-2022-0039175

(51) Int. Cl. H01L 23/528; H01L 27/108; H01L 29/417; H01L 29/08; H01L 23/522

(52) U.S. Cl. CPC H01L 23/5283; H01L 27/10805; H01L 27/1085; H01L 27/10873; H01L 27/10885; H01L 27/10891; H01L 29/41775; H01L 29/0847; H01L 23/5226

(57) ABSTRACT

A semiconductor device includes an extension structure including a first horizontal conductive line extension, a first interlayer insulating layer, a second horizontal conductive line extension, and a second interlayer insulating layer stacked on a substrate and extending in a first horizontal direction, a first contact configured to pass through the second interlayer insulating layer, the second horizontal conductive line extension, and the first interlayer insulating layer and contact the first horizontal conductive line extension, a second contact configured to pass through the second interlayer insulating layer and contact the second horizontal conductive line extension, and a first contact spacer extending between a sidewall of the first contact and the extension structure and configured to electrically isolate the first contact from the second horizontal conductive line extension.

### CROSS-REFERENCE TO RELATED APPLICATION

This application is based on and claims priority under 35 U.S.C. § 119 to Korean Patent Application No. 10-2022-0039175, filed on Mar. 29, 2022, in the Korean Intellectual Property Office, the disclosure of which is incorporated by reference herein in its entirety.

### BACKGROUND

The inventive concepts relate to a semiconductor device and/or a method of manufacturing the same. More specifically, the inventive concepts relate to three-dimensional (3D) memory devices and/or methods of manufacturing the same.

In order to meet consumer demands, semiconductor devices with higher degrees of integration are required. Because the degree of integration of a two-dimensional (2D) memory device is mainly determined by an area occupied by a unit memory cell, the 2D memory device is greatly affected by the level of fine pattern forming technology. However, the development of fine pattern forming technology is reaching its limit. Accordingly, 3D semiconductor devices including 3D arranged memory cells have been proposed. The degree of integration of 3D semiconductor devices may be improved by increasing the number of memory cells stacked in a vertical direction.

### SUMMARY

Some example embodiments of the inventive concepts provide semiconductor devices that are relatively easy to manufacture because it is not necessary to form a stair structure for a contact.

According to an aspect of the inventive concepts, a semiconductor device may include an extension structure including a first horizontal conductive line extension, a first interlayer insulating layer, a second horizontal conductive line extension, and a second interlayer insulating layer that are stacked on a substrate and extending in a first horizontal direction, a first contact configured to pass through the second interlayer insulating layer, the second horizontal conductive line extension, and the first interlayer insulating layer and contact the first horizontal conductive line extension, a second contact configured to pass through the second interlayer insulating layer and contact the second horizontal conductive line extension, and a first contact spacer extending on a sidewall of the first contact configured to electrically isolate the first contact from the second horizontal conductive line extension.

According to another aspect of the inventive concepts, a semiconductor device may include a semiconductor pattern extending in a first horizontal direction and including a first source/drain, a channel, and a second source/drain, a horizontal conductive line extending in a second horizontal direction and intersecting with the semiconductor pattern in a plan view, a gate dielectric layer between the horizontal conductive line and the semiconductor pattern, a capacitor in contact with the second source/drain, a vertical conductive line in contact with the first source/drain and extending in a vertical direction, a first horizontal conductive line extension extending from the horizontal conductive line in the second horizontal direction, a first interlayer insulating layer on the first horizontal conductive line extension, a second horizontal conductive line extension on the first interlayer insulating layer, a second interlayer insulating layer on the second horizontal conductive line extension, a first contact configured to pass through the second interlayer insulating layer, the second horizontal conductive line extension, and the first interlayer insulating layer and contact the first horizontal conductive line extension, a second contact configured to pass through the second interlayer insulating layer and contact the second horizontal conductive line extension, and a first contact spacer extending on a sidewall of the first contact configured to electrically isolate the first contact from the second horizontal conductive line extension.

According to another aspect of the inventive concepts, a semiconductor device may include a first semiconductor pattern extending in a first horizontal direction and including a first source/drain, a first channel, and a second source/drain, a second semiconductor pattern extending in the first horizontal direction, spaced apart from the first semiconductor pattern in a vertical direction, and including a third source/drain, a second channel, and a fourth source/drain, a first horizontal conductive line extending in a second horizontal direction and intersecting with the first semiconductor pattern and the second semiconductor pattern in a plan view, a second horizontal conductive line extending in the second horizontal direction and intersecting with the first semiconductor pattern and the second semiconductor pattern in a plan view, a gate dielectric layer between the first horizontal conductive line and the first semiconductor pattern and between the second horizontal conductive line and the second semiconductor pattern, a first capacitor in contact with the second source/drain, a second capacitor in contact with the fourth source/drain, a vertical conductive line contacting the first source/drain and the third source/drain and extending in the vertical direction, and a first horizontal conductive line extension extending from the first horizontal conductive line in the second horizontal direction, a second horizontal conductive line extension extending from the second horizontal conductive line in the second horizontal direction, a first interlayer insulating layer between the first horizontal conductive line extension and the second horizontal conductive line extension, a second interlayer insulating layer on the second horizontal conductive line extension, a first contact configured to pass through the second interlayer insulating layer, the second horizontal conductive line extension, and the first interlayer insulating layer and contact the first horizontal conductive line extension, a second contact configured to pass through the second interlayer insulating layer and contact the second horizontal conductive line extension, and a first contact spacer extending between a sidewall of the first contact and the extension structure and configured to electrically isolate the first contact from the third horizontal conductive line extension and the second horizontal conductive line extension.

### BRIEF DESCRIPTION OF THE DRAWINGS

Some example embodiments of the inventive concepts will be more clearly understood from the following detailed description taken in conjunction with the accompanying drawings in which:

FIG. 1A is a plan view illustrating a semiconductor device according to an example embodiment;

FIG. 1B is a cross-sectional view taken along line A-A′ of FIG. 1A;

FIG. 1C is a cross-sectional view taken along line B-B′ of FIG. 1A;

FIG. 1D is an enlarged view of region C0 of FIG. 1B:

FIG. 1E is an enlarged view of a region D0 of FIG. 1C;

FIGS. 2A to 2K are cross-sectional views illustrating a method of manufacturing a semiconductor device, according to an example embodiment:

FIGS. 3A to 27A and 3B to 27B are cross-sectional views illustrating a method of manufacturing a semiconductor device, according to an example embodiment; FIGS. 3A to 27A correspond to cross-sectional views taken along line A-A′ in FIG. 1A; FIGS. 3B to 27B correspond to cross-sectional views taken along line B-B′ of FIG. 1A; and

FIG. 28 is a cross-sectional view illustrating a method of manufacturing a semiconductor device, according to an example embodiment and corresponding to a cross-sectional view taken along line A-A′ in FIG. 1A.

### DETAILED DESCRIPTION

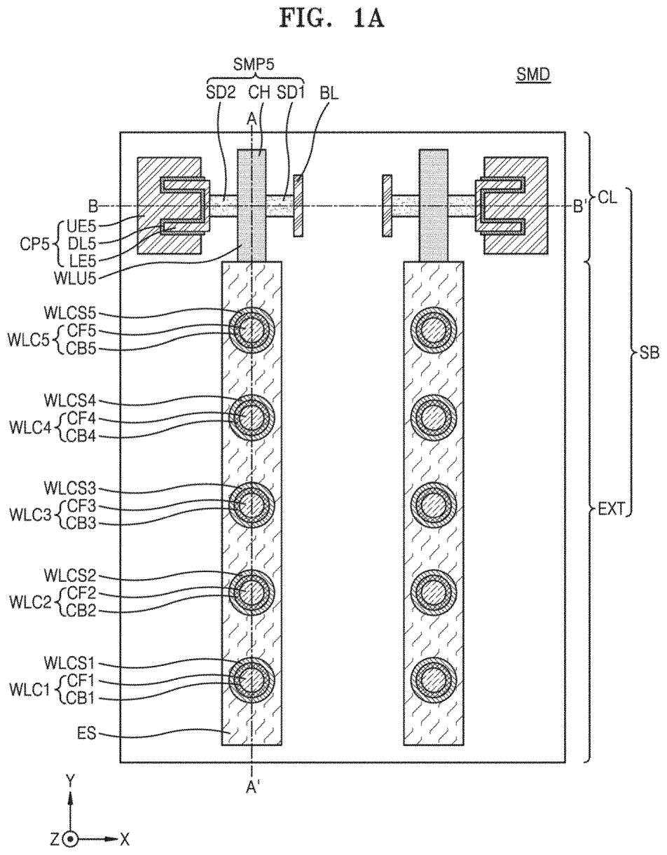

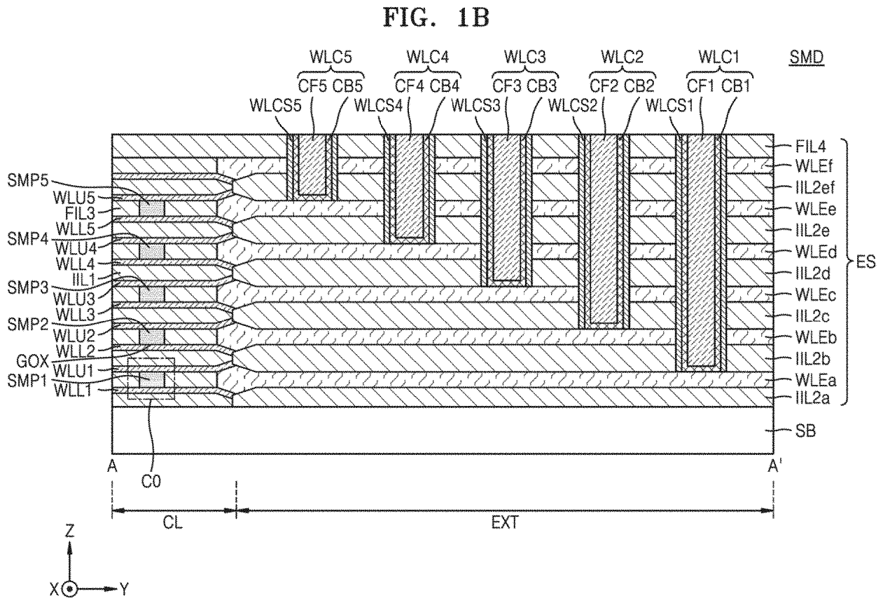

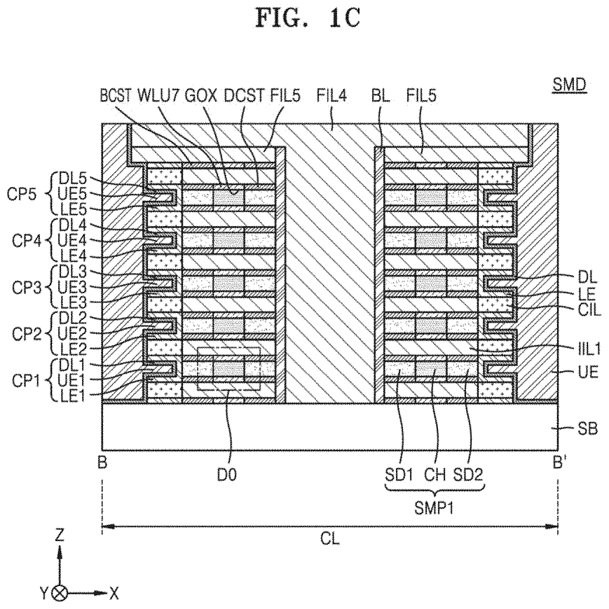

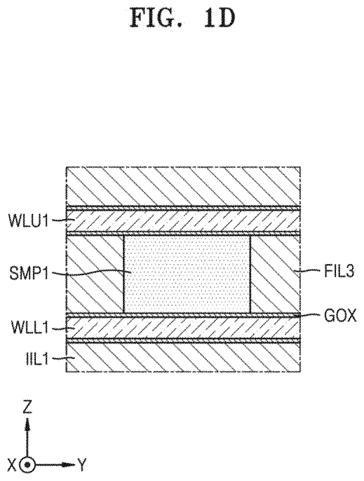

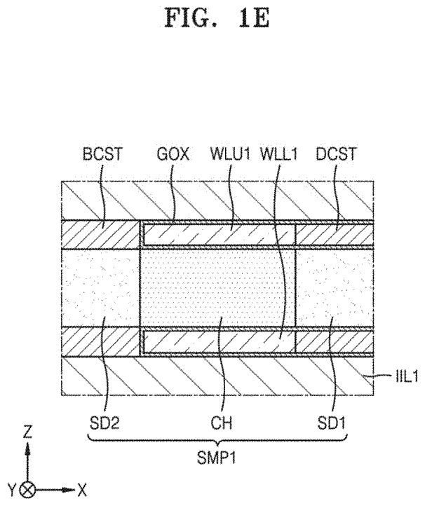

FIG. 1A is a plan view illustrating a semiconductor device according to an example embodiment. FIG. 1B is a cross-sectional view taken along line A-A′ of FIG. 1A. FIG. 1C is a cross-sectional view taken along line B-B′ of FIG. 1A. FIG. 1D is an enlarged view of region C0 of FIG. 1B. FIG. 1E is an enlarged view of a region D0 of FIG. 1C.

Referring to FIGS. 1A to 1E, a semiconductor device SMD may include a substrate SB.

The substrate SB may include a cell region CL and an extension region EXT. The semiconductor device SMD may include an extension structure ES in the extension region EXT. The extension structure ES may extend in a second horizontal direction (Y direction). The extension structure ES may include a first interlayer insulating layer IIL2a, a first horizontal conductive line extension WLEa, a second interlayer insulating layer IIL2b, a second horizontal conductive line extension WLEb, a third interlayer insulating layer IIL2c, a third horizontal conductive line extension WLEc, a fourth interlayer insulating layer IIL2d, a fourth horizontal conductive line extension WLEd, a fifth interlayer insulating layer IIL2e, a fifth horizontal conductive line extension WLEe, a sixth interlayer insulating layer IIL2f, a sixth horizontal conductive line extension WLEf, and an upper filling insulating layer FIL4 which are sequentially stacked in the extension region EXT of the substrate SB in this stated order. FIGS. 1A to 1E show that six horizontal conductive line extensions, for example, the first to sixth horizontal conductive line extensions WLEa to WLEf, are stacked in the extension structure ES, but the number of stacked horizontal conductive line extensions may be modified in various ways.

The first to sixth interlayer insulating layers IIL2a to IIL2f and the upper filling insulating layer FIL4 may include silicon oxide, silicon nitride, a low-k material, or a combination thereof. The first to sixth horizontal conductive line extensions WLEa to WLEf may include tungsten (W), aluminum (Al), copper (Cu), gold (Ag), silver (Au), or a combination thereof. In some example embodiments, each of the first to sixth horizontal conductive line extensions WLEa to WLEf may include a filling layer and a barrier layer surrounding the filling layer. The filling layer may include, for example, tungsten (W), aluminum (A), copper (Cu), gold (Ag), silver (Au), or a combination thereof. The barrier layer may include titanium nitride (TiN), tantalum nitride (TaN), titanium (Ti), tantalum (Ta), or a combination thereof.

The semiconductor device SMD may further include a first contact WLC1 that passes through the second to sixth horizontal conductive line extensions WLEb to WLEf, the second to sixth interlayer insulating layers IIL2b to IIL2f, and the upper filling insulating layer FL4 and is in contact with the first horizontal conductive line extension WLEa. The semiconductor device SMD may further include a first contact spacer WLCS1 extending between the sidewall of the first contact WLC1 and the extension structure ES and configured to electrically isolate the first contact WLC1 from the second to sixth horizontal conductive line extensions WLEb to WLEf. The first contact WLC1 may include a first barrier layer CB1 and a first filling conductive layer CF1. The first barrier layer CB1 may be located on the first horizontal conductive line extension WLEa and the first contact spacer WLCS1, and the first filling conductive layer CF1 may be located on the first barrier layer CB1.

The semiconductor device SMD may further include a second contact WLC2 that passes through the third to sixth horizontal conductive line extensions WLEc to WLEf, the third to sixth interlayer insulating layers IIL2c to IIL2f, and the upper filling insulating layer FL4 and is in contact with the second horizontal conductive extension WLEb. The semiconductor device SMD may further include a second contact spacer WLCS2 extending between the sidewall of the second contact WLC2 and the extension structure ES and configured to electrically isolate the second contact WLC2 from the third to sixth horizontal conductive line extensions WLEc to WLEf. The second contact WLC2 may include a second barrier layer CB2 and a second filling conductive layer CF2. The second barrier layer CB2 may be located on the second horizontal conductive line extension WLEb and the second contact spacer SLCS2. The second filling conductive layer CF2 may be disposed on the second barrier layer CB2. The second contact WLC2 may be spaced apart from the first contact WLC1 in the second horizontal direction (Y direction).

The semiconductor device SMD may further include a third contact WLC3 that passes through the fourth to sixth horizontal conductive line extensions WLEd to WLEf, the fourth to sixth interlayer insulating layers IIL2d to IIL2f, and the upper filling insulating layer FL4 and is in contact with the third horizontal conductive line extension WLEc. The semiconductor device SMD may further include a third contact spacer WLCS3 extending between the sidewall of the third contact WLC3 and the extension structure ES and configured to electrically isolate the third contact WLC3 from the fourth to sixth horizontal conductive line extensions WLEd to WLEf. The third contact WLC3 may include a third barrier layer CB3 and a third filling conductive layer CF3. The third barrier layer CB3 may be located on the third horizontal conductive line extension WLEc and the third contact spacer WLCS3, and the third filling conductive layer CF3 may be located on the third barrier layer CB3. The third contact WLC3 may be spaced apart from the second contact WLC2 in the second horizontal direction (Y direction).

The semiconductor device SMD may further include a fourth contact WLC4 that passes through the fifth and sixth horizontal conductive line extensions WLEe and WLEf, the fifth and sixth interlayer insulating layers IIL2e and IIL2f, and the upper filling insulating layer FL4 and is in contact with the fourth horizontal conductive line extension WLEd. The semiconductor device SMD may further include a fourth contact spacer WLCS4 extending between the sidewall of the fourth contact WLC4 and the extension structure ES and configured to electrically isolate the fourth contact WLC4 from the fifth and sixth horizontal conductive line extensions WLEe and WLEf. The fourth contact WLC4 may include a fourth barrier layer CB4 and a fourth filling conductive layer CF4. The fourth barrier layer CB4 may be located on the fourth horizontal conductive line extension WLEd and the fourth contact spacer WLCS4, and the fourth filling conductive layer CF4 may be located on the fourth barrier layer CB4. The fourth contact WLC4 may be spaced apart from the third contact WLC3 in the second horizontal direction (Y direction).

The semiconductor device SMD may further include a fifth contact WLC5 that passes through the sixth horizontal conductive line extension WLEf, the sixth interlayer insulating layer IIL2f, and the upper filling insulating layer FL4 and is in contact with the fifth horizontal conductive line extension WLEe. The semiconductor device SMD may further include a contact spacer WLCS5 extending between the sidewall of the fifth contact WLC5 and the extension structure ES and configured to electrically isolate the fifth contact WLC5 from the sixth horizontal conductive line extension WLEf. The fifth contact WLC5 may include a fifth barrier layer CB5 and a fifth filling conductive layer CF5. The fifth barrier layer CB5 may be located on the fifth horizontal conductive line extension WLEe and the fifth contact spacer WLCS5, and the fifth filling conductive layer CF5 may be located on the fifth barrier layer CB5. The fifth contact WLC5 may be spaced apart from the fourth contact WLC4 in the second horizontal direction (Y direction).

Each of the first to fifth filling conductive layers CF1 to CF5 may include tungsten (W), aluminum (Al), copper (Cu), gold (Au), silver (Ag), or a combination thereof. Each of the first to fifth barrier layers CB1 to CB5 may include titanium nitride (TiN), tantalum nitride (TaN), titanium (Ti), tantalum (Ta), or a combination thereof. Each of the first to fifth contact spacers WLCS1 to WLCS5 may include silicon oxide, silicon nitride, or a combination thereof.

Each of the first lower horizontal conductive line WLL1 and the first upper horizontal conductive line WLU1 may extend in the second horizontal direction (Y direction) in a cell region CL of the substrate SB and be in contact with one end of the first horizontal conductive line extension WLEa. Each of the second lower horizontal conductive line WLL2 and the second upper horizontal conductive line WLU2 may extend in the second horizontal direction (Y direction) in the cell region CL of the substrate SB and be in contact with one end of the second horizontal conductive line extension WLEb. Each of the third lower horizontal conductive line WLL3 and the third upper horizontal conductive line WLU3 may extend in the second horizontal direction (Y direction) in the cell region CL of the substrate SB and be in contact with one end of the third horizontal conductive line extension WLEc. Each of the fourth lower horizontal conductive line WLL4 and the fourth upper horizontal conductive line WLU4 may extend in the second horizontal direction (Y direction) in the cell region CL of the substrate SB and be in contact with one end of the fourth horizontal conductive line extension WLEd.

Each of the fifth lower horizontal conductive line WLL5 and the fifth upper horizontal conductive line WLU5 may extend in a fifth horizontal direction (Y direction) in the cell region CL of the substrate SB, and be in contact with one end of the fifth horizontal conductive line extension WLEe.

The first lower horizontal conductive line WLL1, the first upper horizontal conductive line WLU1, the second lower horizontal conductive line WLL2, the second upper horizontal conductive line WLU2, the third lower horizontal conductive line WLL3, the third upper horizontal conductive line WLU3, the fourth lower horizontal conductive line WLL4, the fourth upper horizontal conductive line WLU4, the fifth lower horizontal conductive line WLL5, and the fifth lower horizontal conductive line WLU5 may be sequentially stacked in the cell region CL of the substrate SB. The first lower horizontal conductive line WLL1, the first upper horizontal conductive line WLU1, the second lower horizontal conductive line WLL2, the second upper horizontal conductive line WLU2, the third lower horizontal conductive line WLL3 the third upper horizontal conductive line WLU3, the fourth lower horizontal conductive line WLL4, the fourth upper horizontal conductive line WLU4, the fifth lower horizontal conductive line WLL5, and the fifth lower horizontal conductive line WLU5 may be spaced apart from each other in the vertical direction (Z direction).

Each of the first lower horizontal conductive line WLL1, the first upper horizontal conductive line WLU1, the second lower horizontal conductive line WLL2, the second upper horizontal conductive line WLU2, the third lower horizontal conductive line WLL3, the third upper horizontal conductive line WLU3, the fourth lower horizontal conductive line WLL4, the fourth upper horizontal conductive line WLU4, the fifth lower horizontal conductive line WLL5, and the fifth lower horizontal conductive line WLU5 may include tungsten (W), aluminum (Al), copper (Cu), gold (Au), silver (Ag), or a combination thereof. In some example embodiments, each of the first lower horizontal conductive line WLL1, the first upper horizontal conductive line WLU1, the second lower horizontal conductive line WLL2, the second upper horizontal conductive line WLU2, the third lower horizontal conductive line WLL3, the third upper horizontal conductive line WLU3, the fourth lower horizontal conductive line WLL4, the fourth upper horizontal conductive line WLU4, the fifth lower horizontal conductive line WLL5, and the fifth lower horizontal conductive line WLU5 may include a filling layer and a barrier layer surrounding the filling layer. The filling layer may include, for example, tungsten (W), aluminum (Al), copper (Cu), gold (Ag), silver (Au), or a combination thereof. The barrier layer may include titanium nitride (TiN), tantalum nitride (TaN), titanium (Ti), tantalum (Ta), or a combination thereof.

The semiconductor device SMD may further include a first semiconductor pattern SMP1 between the first lower horizontal conductive line WLL1 and the first upper horizontal conductive line WLU1. The semiconductor device SMD may further include a second semiconductor pattern SMP2 between the second lower horizontal conductive line WLL2 and the second upper horizontal conductive line WLLU2. The semiconductor device SMD may further include a third semiconductor pattern SMP3 between the third lower horizontal conductive line WLL3 and the third upper horizontal conductive line WLLU3. The semiconductor device SMD may further include a fourth semiconductor pattern SMP4 between the fourth lower horizontal conductive line WLL4 and the fourth upper horizontal conductive line WLLU4. The semiconductor device SMD may further include a fifth semiconductor pattern SMP5 between the fifth lower horizontal conductive line WLL5 and the fifth upper horizontal conductive line WLLU5. The first to fifth semiconductor patterns SMP1 to SMP5 may be sequentially stacked in the cell region CL of the substrate SB, and may be spaced apart from each other in the vertical direction (Z direction). Each of the first to fourth semiconductor patterns SMP1 to SMP5 may extend in a first horizontal direction (X direction).

As shown in FIGS. 1D and 1E, the semiconductor device SMD may further include a gate dielectric layer GOX extending between the first lower horizontal conductive line WLL1 and the first semiconductor pattern SMP1, between the first upper horizontal conductive line WLU1 and the first semiconductor pattern SMP1, between the second lower horizontal conductive line WLL2 and the second semiconductor pattern SMP2, between the second upper horizontal conductive line WLU2 and the second semiconductor pattern SMP2, between the third lower horizontal conductive line WLL3 and the third semiconductor pattern SMP3, between the third upper horizontal conductive line WLU3 and the third semiconductor pattern SMP3, between the fourth lower horizontal conductive line WLL4 and the fourth semiconductor pattern SMP4, between the fourth upper horizontal conductive line WLU4 and the fourth semiconductor pattern SMP4, between the fifth lower horizontal conductive line WLL5 and the fifth semiconductor pattern SMP5, and between the fifth upper horizontal conductive line WLU5 and the fifth semiconductor patterns SMP5. The gate dielectric layer GOX may include silicon oxide, aluminum oxide, zirconium oxide, hafnium oxide, or a combination thereof.

As shown in FIG. 1A, each of the first to fifth semiconductor patterns SMP1 to SMP5 may include a channel CH, a first source/drain SD1, and a second source/drain SD2. The channel CH may intersect with a corresponding pair from among the first lower horizontal conductive line WLL1 and the first upper horizontal conductive line WLU1, the second lower horizontal conductive line WLL2 and the second upper horizontal conductive line WLU2, the third lower horizontal conductive line WLL3 and the third upper horizontal conductive line WLU3, the fourth lower horizontal conductive line WLL4 and the fourth upper horizontal conductive line WLU4, and the fifth lower horizontal conductive line WLL5 and the fifth lower horizontal conductive line WLU5. The first source/drain SD1 may be at one end of the channel CH, and the second source/drain SD2 may be at an opposite end of the channel CH. Each of the first to fifth semiconductor patterns SMP1 to SMP5 may include a semiconductor material (e.g., silicon (Si) or germanium (Ge)). The first source/drain SD1 and the second source/drain SD2 may be doped with impurities.

The semiconductor device SMD may further include an interlayer insulating pattern IIL1 between the first upper horizontal conductive line WLU1 and the second lower horizontal conductive line WLL2, between the second upper horizontal conductive line WLU2 and the third lower horizontal conductive line WLL3, between the third upper part between the horizontal conductive line WLU3 and the fourth lower horizontal conductive line WLL4, and between the fourth upper horizontal conductive line WLU4 and the fifth lower horizontal conductive line WLL5, respectively. The interlayer insulating pattern ILI may include, for example, silicon oxide, silicon nitride, a low-k material, or a combination thereof.

The semiconductor device SMD may further include a third filling layer FIL3 between the first lower horizontal conductive line WLL1 and the first upper horizontal conductive line WLU1, between the second lower horizontal conductive line WLL2 and the second upper horizontal conductive line WLU2, between the third lower horizontal conductive line WLL3 and the third upper horizontal conductive line WLU3, between the fourth lower horizontal conductive line WLL4 and the fourth upper horizontal conductive line WLU4, and between the fifth lower horizontal conductive line WLL5 and the fifth upper horizontal conductive line WLU5. The third filling layer FIL3 may include, for example, silicon oxide, silicon nitride, a low-k material, or a combination thereof.

The semiconductor device SMD may further include a vertical conductive line BL that is in contact with the first source/drain SD1 of each of the first to fifth semiconductor patterns SMP1 to SMP5 and extends in the vertical direction (Z direction). The vertical conductive line BL may include, for example, tungsten (W), aluminum (Al), copper (Cu) gold (Au), silver (Ag), or a combination thereof.

The semiconductor device SMD may further include a first capacitor CP1 in contact with the second source/drain SD2 of the first semiconductor pattern SMP1, a second capacitor CP2 in contact with the second source/drain SD2 of the second semiconductor pattern SMP2, a third capacitor CP3 in contact with the second source/drain SD2 of the third semiconductor pattern SMP3, a fourth capacitor CP4 in contact with the second source/drain SD2 of the fourth semiconductor pattern SMP4, and a fifth capacitor CP5 in contact with the second source/drain SD2 of the fifth semiconductor pattern SMP5.

The first capacitor CP1 may include a first lower electrode LE1 in contact with the second source/drain SD2 of the first semiconductor pattern SMP1, a first capacitor dielectric layer DL1 on the first lower electrode LE1, and a first upper electrode UE1 on the first capacitor dielectric layer DL1. The second capacitor CP2 may include a second lower electrode LE2 in contact with the second source/drain SD2 of the second semiconductor pattern SMP2, a second capacitor dielectric layer DL2 on the second lower electrode LE2, and a second upper electrode UE2 on the second capacitor dielectric layer DL2. The third capacitor CP3 may include a third lower electrode LE3 in contact with the second source/drain SD2 of the third semiconductor pattern SMP3, a third capacitor dielectric layer DL3 on the third lower electrode LE3, and a third upper electrode UE3 on the third capacitor dielectric layer DL3. The fourth capacitor CP4 may include a fourth lower electrode LFA in contact with the second source/drain SD2 of the fourth semiconductor pattern SMP4, a fourth capacitor dielectric layer DL4 on the fourth lower electrode LE4, and a fourth upper electrode UE4 on the fourth capacitor dielectric layer DL4. The fifth capacitor CP5 may include a fifth lower electrode LE5 in contact with the second source/drain SD2 of the fifth semiconductor pattern SMP5, a fifth capacitor dielectric layer DL5 on the fifth lower electrode LE5, and a fifth upper electrode UE5 on the fifth capacitor dielectric layer DL.

Each of the first to fifth lower electrodes LE1 to LE5 and each of the first to fifth upper electrodes UE1 to UE5 may include, for example, titanium nitride (TiN). Each of the first to fifth capacitor dielectric layers DL1 to DL5 may include, for example, aluminum oxide, zirconium oxide, hafnium oxide, or a combination thereof.

In some example embodiments, the first to fifth capacitor dielectric layers DL1 to DL5 may be integrally formed. That is, no physical boundary may exist between the first to fifth capacitor dielectric layers DL1 to DL5. The first to fifth upper electrodes UE1 to UE5 may be integrally formed. That is, no physical boundary may exist between the first to fifth upper electrodes UE1 to UE5.

The semiconductor device SMD may further include a fourth filling insulating layer FIL4 and a fifth insulating filling insulating layer FIL5. The fourth filling insulating layer FIL4 may fill between the two vertical conductive lines BL and may cover the fifth insulating filling layer FIL5. Each of the fourth filling insulating layer FIL4 and the fifth filling insulating layer FIL5 may include, for example, silicon oxide, silicon nitride, a low-k material, or a combination thereof.

As shown in FIG. 1E, the semiconductor device SMD may further include a first insulating pattern DCST located between the interlayer insulating pattern ILI and the first source/drain SD1 and located on one side of the first upper horizontal conductive line WLU1. The first insulating pattern DCST may include, for example, silicon nitride. The semiconductor device SMD may further include a second insulating pattern BCST located between the interlayer insulating pattern IIL1 and the second source/drain SD2 and located on the opposite side of the first upper horizontal conductive line WLU1. The second insulating pattern BCST may include, for example, silicon nitride.

As shown in FIG. 1C, the semiconductor device SMD may further include a capacitor insulating layer CIL between the first lower electrode LE1 and the second lower electrode LE2, between the second lower electrode LE2 and the third lower electrode LE3, between the third lower electrode LE3 and the fourth lower electrode LE4, and between the fourth lower electrode LE4 and the fifth lower electrode LE5, respectively. The capacitor insulating layer CIL may include, for example, silicon oxide, silicon nitride, a low-k material, or a combination thereof.

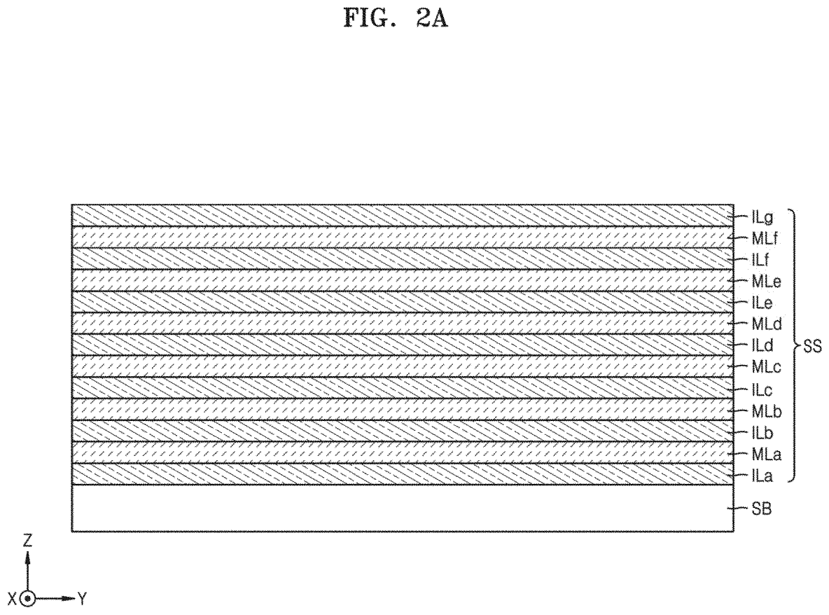

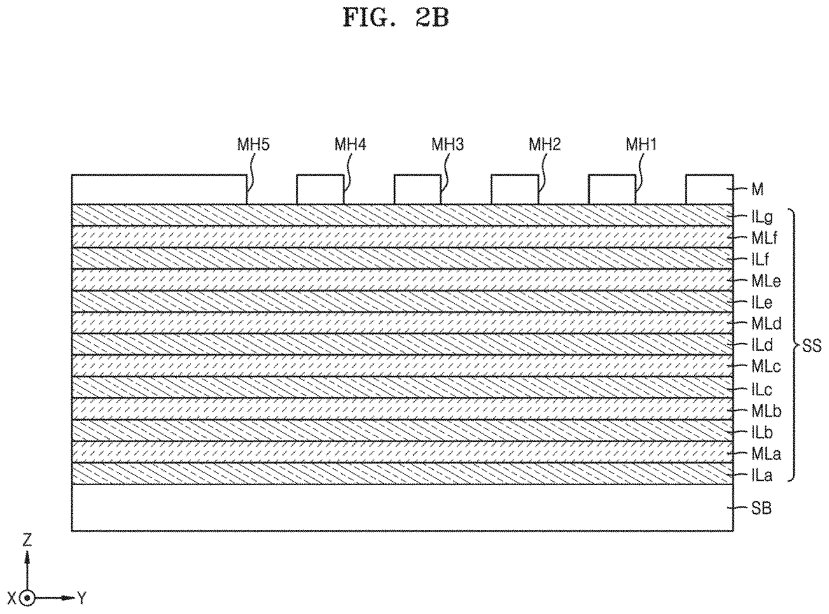

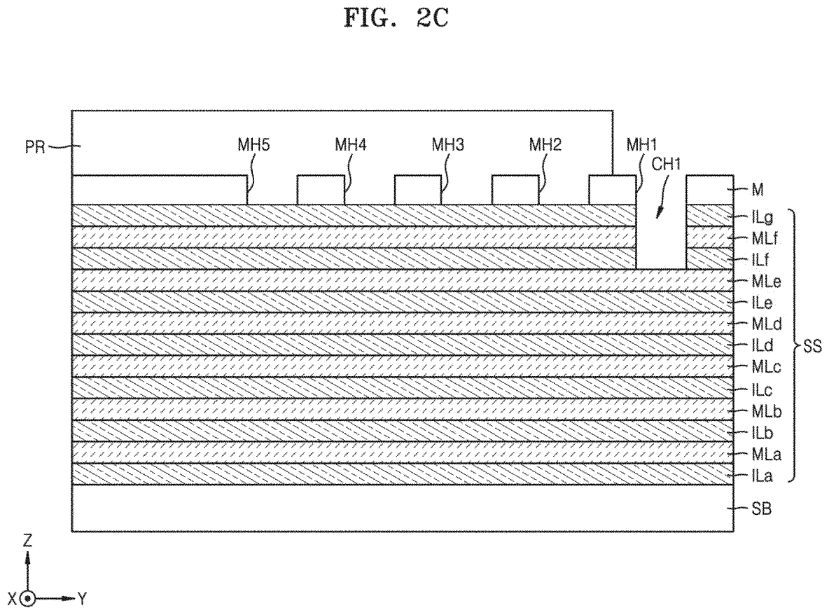

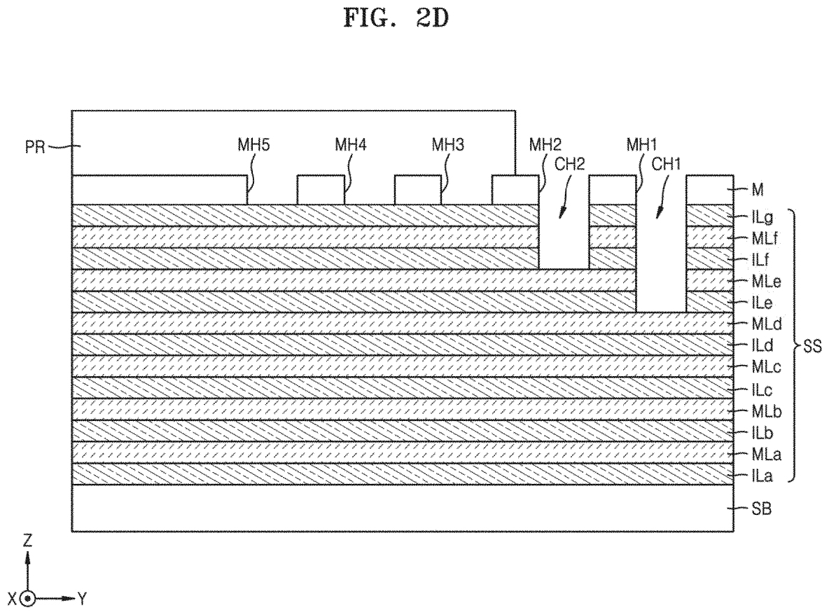

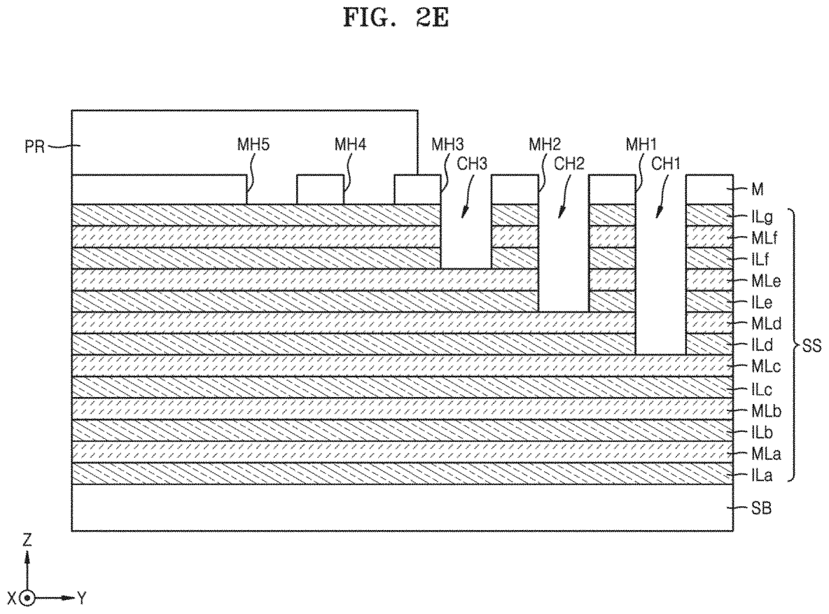

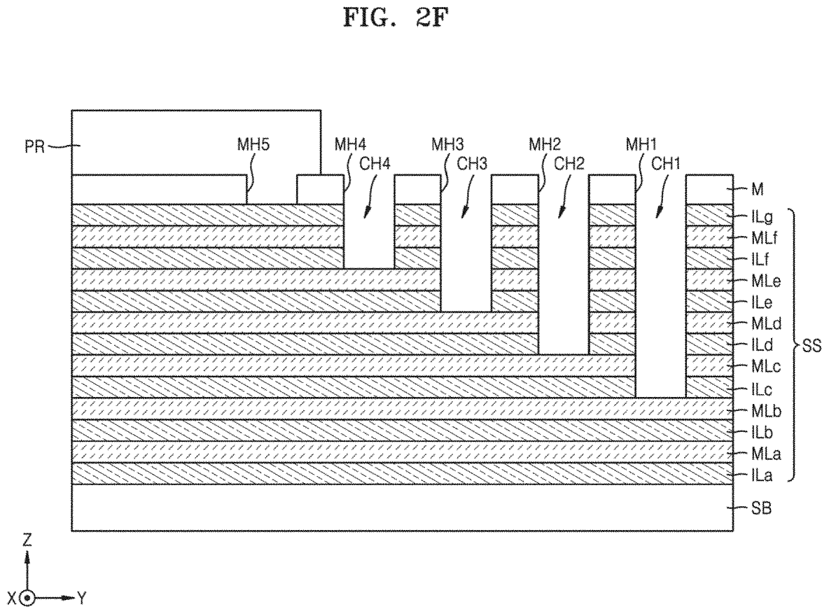

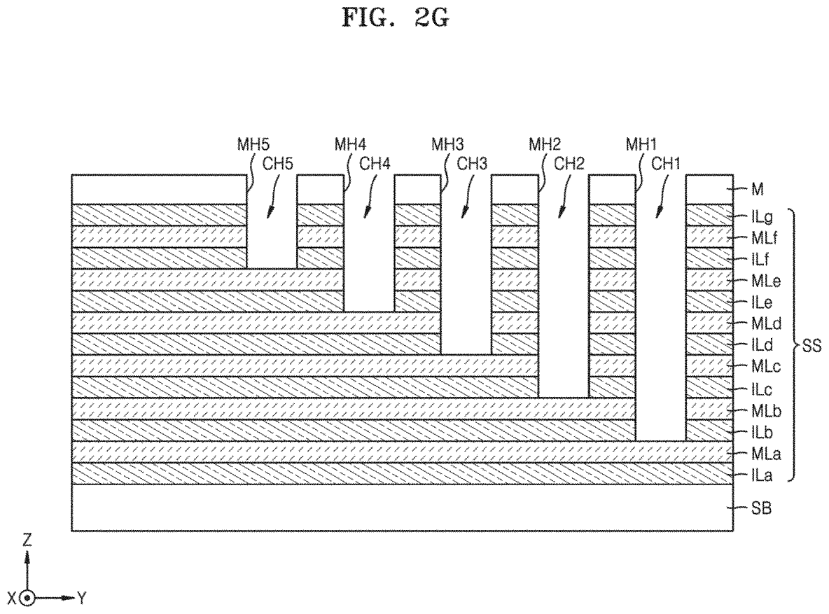

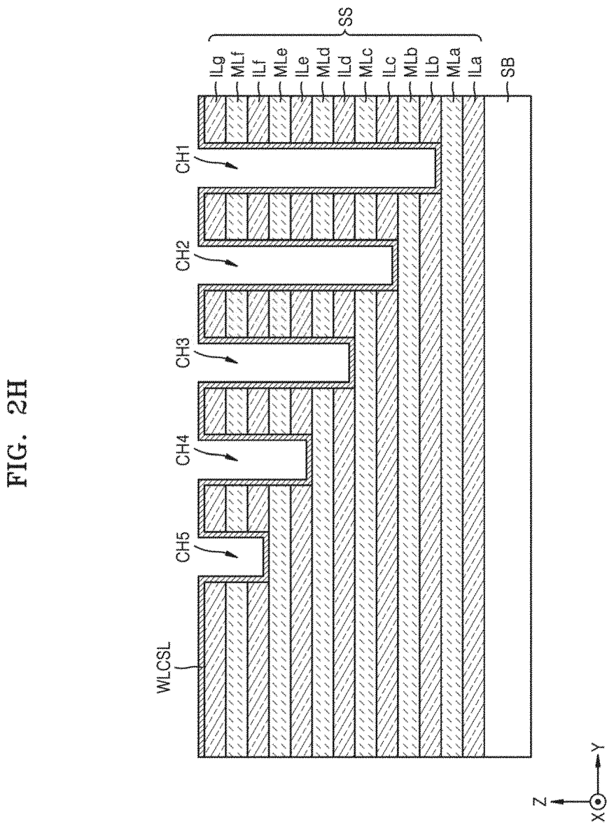

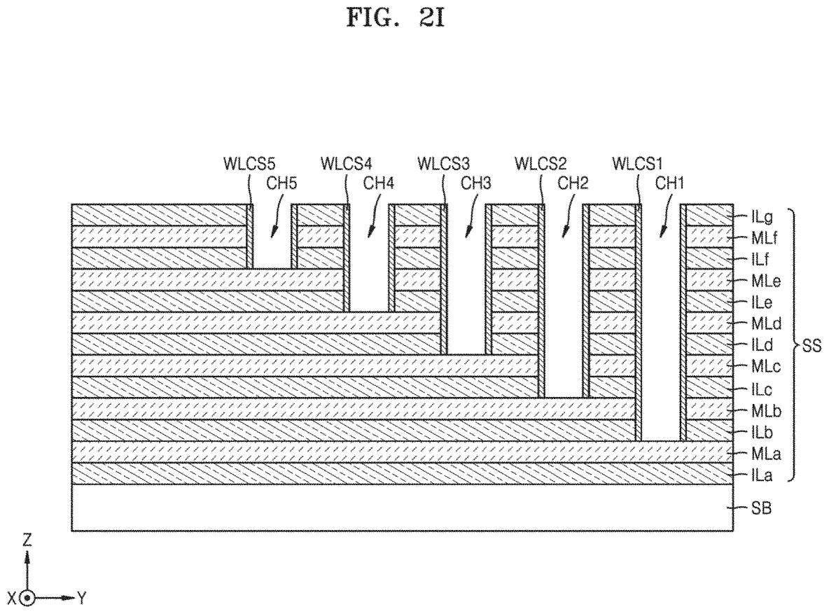

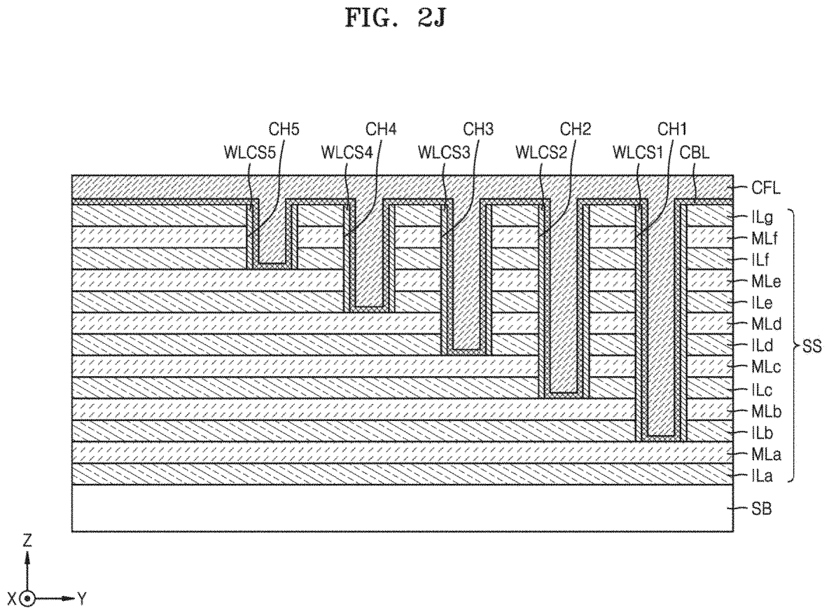

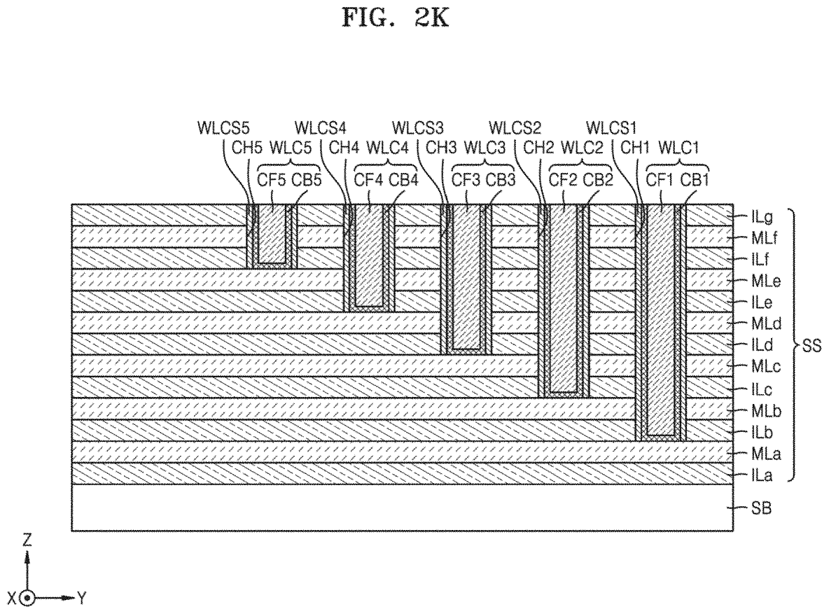

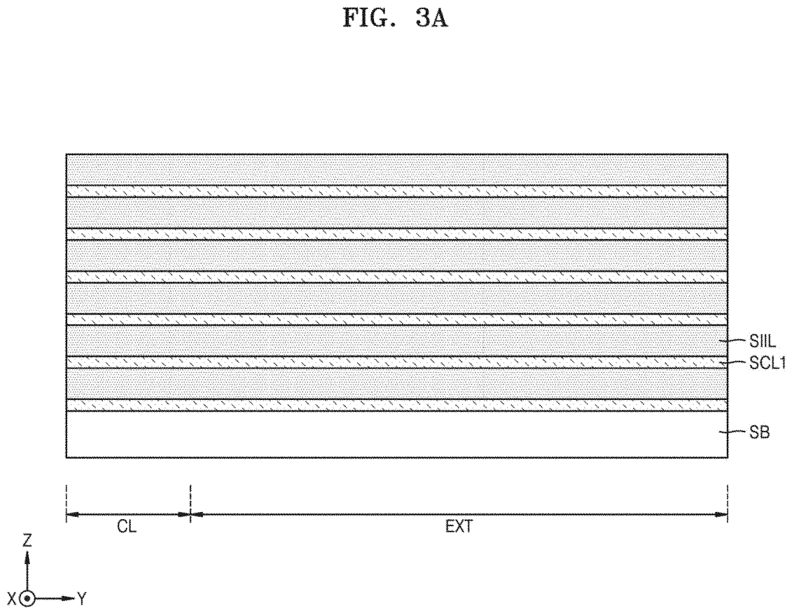

FIGS. 2A to 2K are cross-sectional views illustrating a method of manufacturing a semiconductor device, according to an example embodiment.

Referring to FIG. 2A, a stacked structure SS may be formed by alternately stacking first to seventh insulating layers ILa to ILg and first to sixth material layers MLa to MLf on the substrate SB. The first to sixth material layers MLa to MLf may include a conductive material (e.g., tungsten) or a semiconductor material (e.g., silicon).

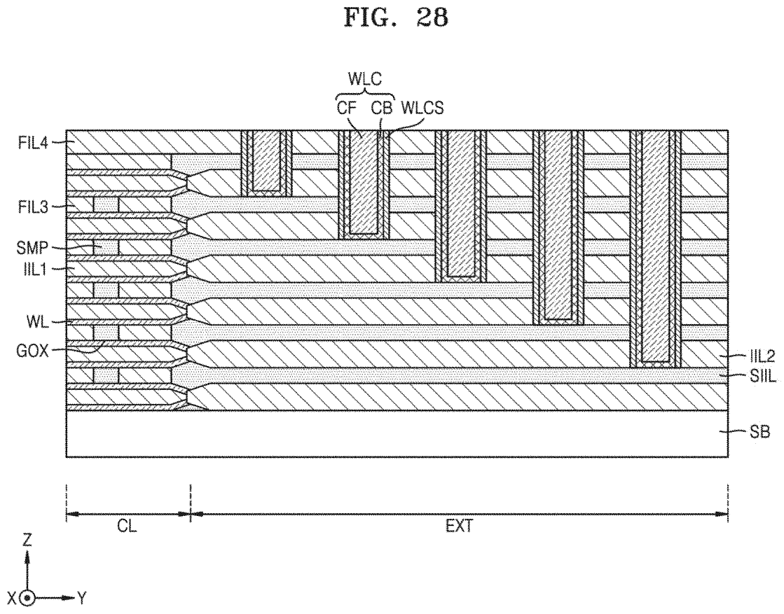

Referring to FIG. 28, a lower mask M having first to fifth mask holes MH1 to MH5 may be formed on the seventh insulating layer ILg. The first to fifth mask holes MH1 to MH5 may pass through the lower mask M in the vertical direction (Z direction) to expose the seventh insulating layer ILg. In some example embodiments, the lower mask M may include a metal.

Referring to FIG. 2C, an upper mask PR covering the second to fifth mask holes MH2 to MH5 and exposing the first mask hole MH1 may be formed on the lower mask M. The upper mask PR may include, for example, photoresist. A first contact hole CH1 passing through the seventh insulating layer ILg, the sixth material layer MLf, and the sixth insulating layer ILf to expose the fifth material layer MLe may be formed. The first contact hole CH1 may be aligned with the first mask hole MH1.

Referring to FIG. 2D, the upper mask PR may be trimmed to expose the first mask hole M1 and the second mask hole MH2. Next, a second contact hole CH2 passing through the seventh insulating layer ILg, the sixth material layer MLU, and the sixth insulating layer ILf to expose the fifth material layer MLe may be formed. The second contact hole CH2 may be aligned with the second mask hole MH2. While the second contact hole CH2 is formed, the first contact hole CH may further pass through the fifth material layer MLe and the fifth insulating layer lie and expand to expose the fourth material layer MLd.

Referring to FIG. 2E, the upper mask PR may be trimmed to expose the first to third mask holes MH1 to MH3. Next, a third contact hole CH3 passing through the seventh insulating layer ILg, the sixth material layer MU, and the sixth insulating layer ILf to expose the fifth material layer MLe may be formed. The third contact hole CH3 may be aligned with the third mask hole MH3. While the third contact hole CH3 is formed, the second contact hole CH2 may further pass through the fifth material layer MLe and the fifth insulating layer lie and expand to expose the fourth material layer MLd. While the third contact hole CH3 is formed, the first contact hole CH1 may further pass through the fourth material layer MLd and the fourth insulating layer ILd and expand to expose the third material layer MLc.

Referring to FIG. 2F, the upper mask PR may be trimmed to expose the first to fourth mask holes MH1 to MH4. Next, a fourth contact hole CH4 passing through the seventh insulating layer ILg, the sixth material layer MU, and the sixth insulating layer ILf to expose the fifth material layer MLe may be formed. The fourth contact hole CH4 may be aligned with the fourth mask hole MH4. While the fourth contact hole CH4 is formed, the third contact hole CH3 may further pass through the fifth material layer MLe and the fifth insulating layer ie and expand to expose the fourth material layer MLd. While the fourth contact hole CH4 is formed, the second contact hole CH2 may further pass through the fourth material layer ML and the fourth insulating layer ILd and expand to expose the third material layer MLc. While the fourth contact hole CH4 is formed, the first contact hole CH1 may further pass through the third material layer MLc and the third insulating layer ILc and expand to expose the second material layer MLb.

Referring to FIG. 2G, the upper mask PR may be removed, and the first to fifth mask holes MH1 to MH4 may be exposed. Next, a fifth contact hole CH5 passing through the seventh insulating layer ILg, the sixth material layer MLf, and the sixth insulating layer ILf to expose the fifth material layer MLe may be formed. The fifth contact hole CH5 may be aligned with the fifth mask hole MH5. While the fifth contact hole CH5 is formed, the fourth contact hole CH4 may further pass through the fifth material layer MLe and the fifth insulating layer lie and expand to expose the fourth material layer MLd. While the fifth contact hole CH5 is formed, the third contact hole CH3 may further pass through the fourth material layer MLd and the fourth insulating layer ILd and expand to expose the third material layer MLc. While the fifth contact hole CH5 is formed, the second contact hole CH2 may further pass through the third material layer MLc and the third insulating layer ILc and expand to expose the second material layer MLb. While the fifth contact hole CH5 is formed, the first contact hole CH1 may further pass through the second material layer MLb and the second insulating layer ILb and expand to expose the first material layer MLa.

Referring to FIG. 2H, the lower mask M may be removed. Next, a contact spacer layer WLCSL may be formed on side surfaces and the bottom of each of the first to fifth contact holes CH1 to CH5 and on the upper surface of the seventh insulating layer ILg.

Referring to FIG. 2I, the contact spacer layer WLCSL (see FIG. 2H) on the bottom of each of the first to fifth contact holes CH1 to CH5 and the upper surface of the seventh insulating layer ILg may be removed through anisotropic etching. Accordingly, first to fifth contact spacers WLCS1 to SLCS5 may be formed on the side surfaces of the first to fifth contact holes CH1 to CH5, respectively.

Referring to FIG. 2J, a barrier layer CBL may be formed on the bottom of each of the first to fifth contact holes CH1 to CH5, the side surfaces of each of the first to fifth contact spacers WLCS1 to WLCS5, and the upper surface of the seventh insulating layer ILg. Next, a filling conductive layer CFL may be formed on the barrier layer CBL.

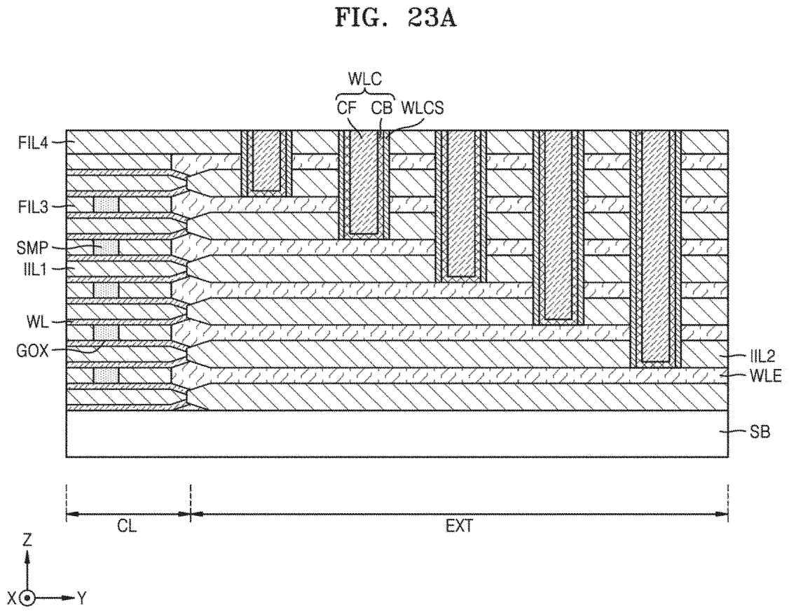

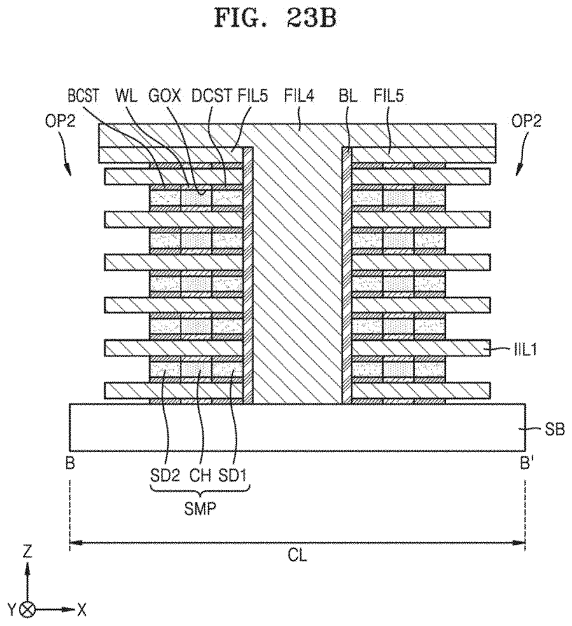

Referring to FIGS. 23 and 2K, the barrier layer CBL and the filling conductive layer CFL on the upper surface of the seventh insulating layer ILg may be removed. For example, chemical mechanical polish (CMP) or etch back may be used. Thus, a first contact WLC1 including the first barrier layer CB1 and the first filling conductive layer CF1 may be formed in the first contact hole CH1, a second contact WLC2 including the second barrier layer CB2 and the second filling conductive layer CF2 may be formed in the second contact hole CH2, a third contact WLC3 including the third barrier layer CB3 and the third filling conductive layer CF3 may be formed in the third contact hole CH3, a fourth contact WLC4 including the fourth barrier layer CB4 and the fourth filling conductive layer CF4 may be formed in the fourth contact hole CH4, and a fifth contact WLC5 including the fifth barrier layer CB5 and the fifth filling conductive layer CF5 may be formed in the fifth contact hole CH5.

According to the method described with reference to FIGS. 2A to 2K, the first to fifth contacts WLC1 to WLC5 contacting the first to fifth material layers MLa to MLe, respectively, may be formed without having to pattern the stacked structure SS in a stair shape.

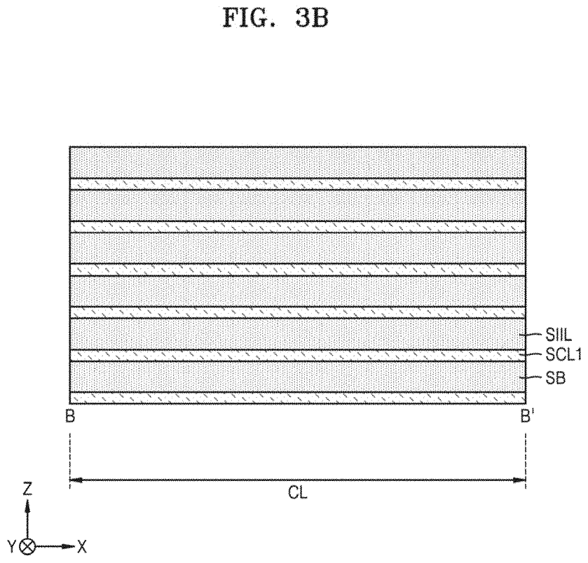

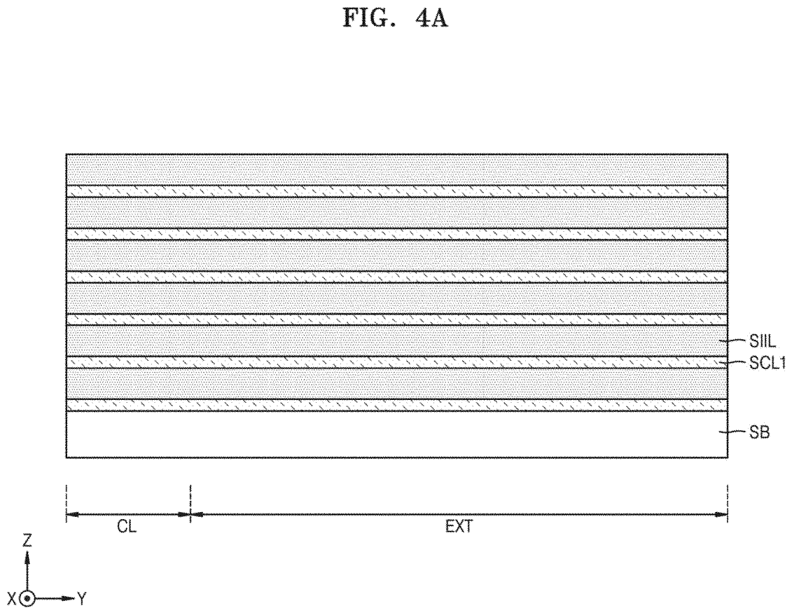

FIGS. 3A to 27A and 3B to 27B are cross-sectional views illustrating a method of manufacturing a semiconductor device, according to an example embodiment. FIGS. 3A to 27A correspond to cross-sectional views taken along line A-A′ in FIG. 1A. FIGS. 3B to 27B correspond to cross-sectional views taken along line B-B′ of FIG. 1A.

Referring to FIGS. 3A and 3B, a plurality of first sacrificial layers SCL1 and a plurality of semiconductor layers SIIL may be alternately formed in the cell region CL and the extension region EXT of the substrate SB. In some example embodiments, each of the plurality of first sacrificial layers SCL1 may include germanium (Ge) or silicon (Si)-germanium (Ge), and each of the plurality of semiconductor layers SIIL may include silicon (Si).

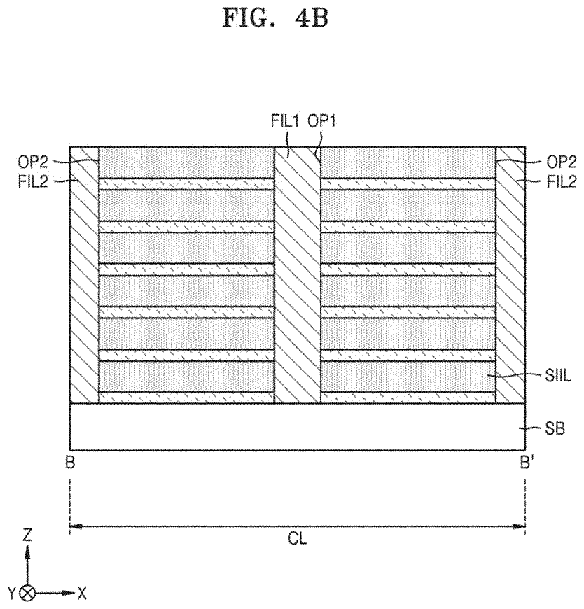

Referring to FIGS. 4A and 48, a first opening OP1 and second openings OP2 that pass through the plurality of first sacrificial layers SCL1 and the plurality of semiconductor layers SIIL may be formed in the cell region CL. The first opening OP1 may be located between the two second openings OP2. The first opening OP1 may be filled with a first filling layer FIL1 and the second openings OP2 may be filled with a second filling layer FIL2. Each of the first filling layer FIL1 and the second filling layer FIL2 may include, for example, silicon oxide, silicon nitride, a low-k material, or a combination thereof.

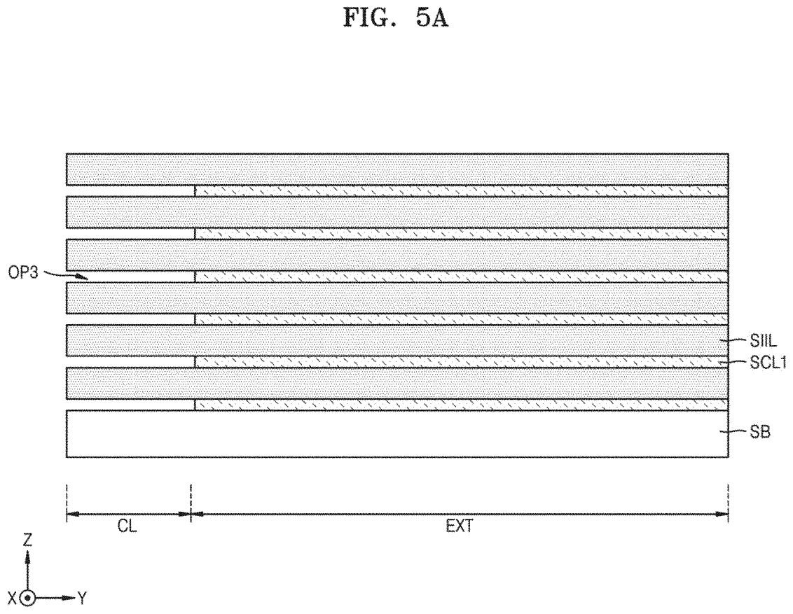

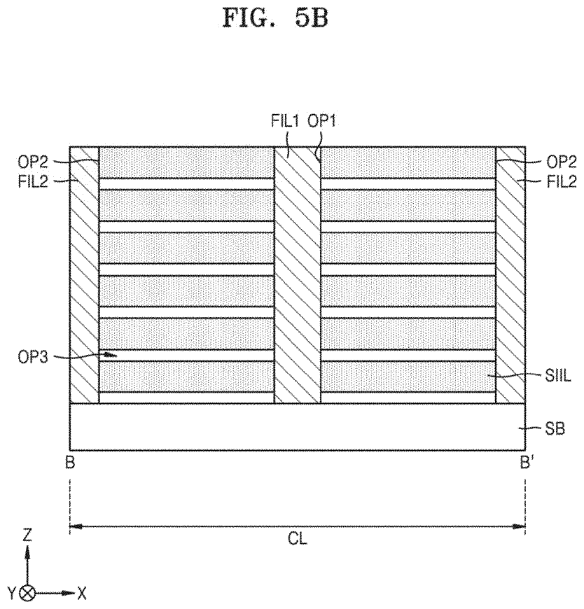

Referring to FIGS. 5A and 5B, the first sacrificial layer SCL1 of the cell region CL may be removed. Thus, third openings OP3 may be formed between the plurality of semiconductor layers SIIL.

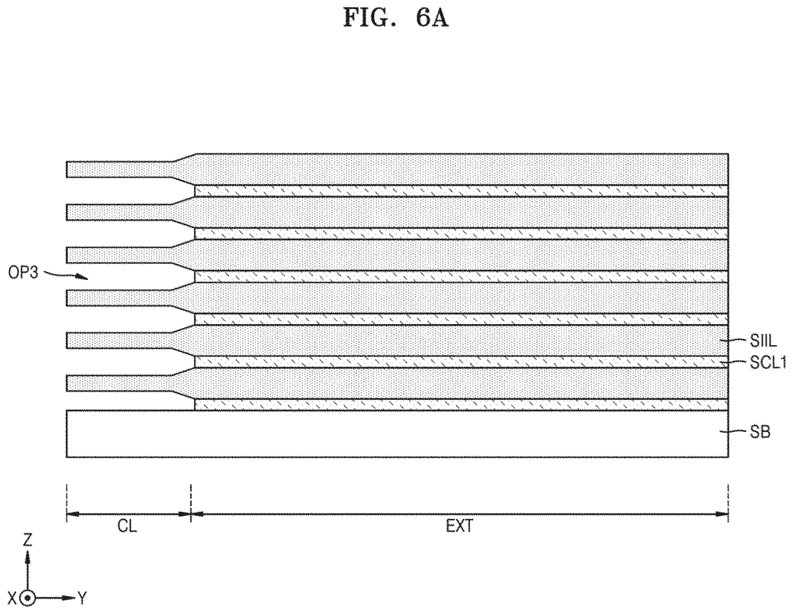

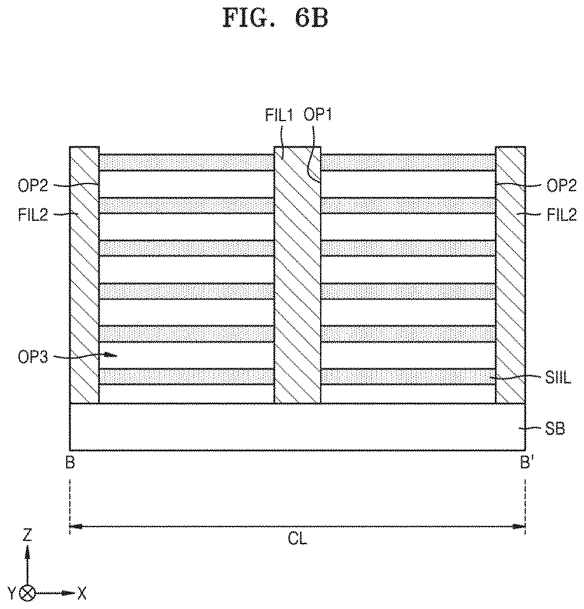

Referring to FIGS. 6A and 6B, the plurality of semiconductor layers SIIL may be thinner in the cell region CL than in the extension region EXT. That is, the third openings OP3 may expand.

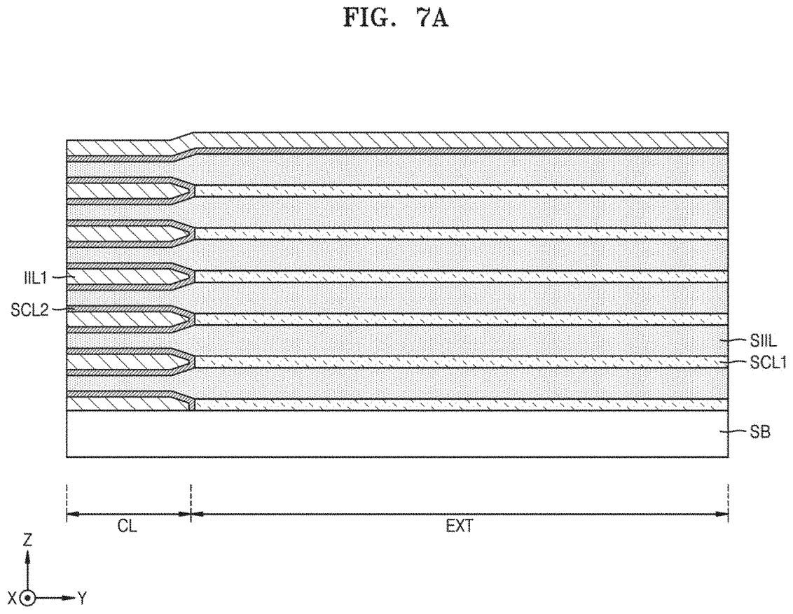

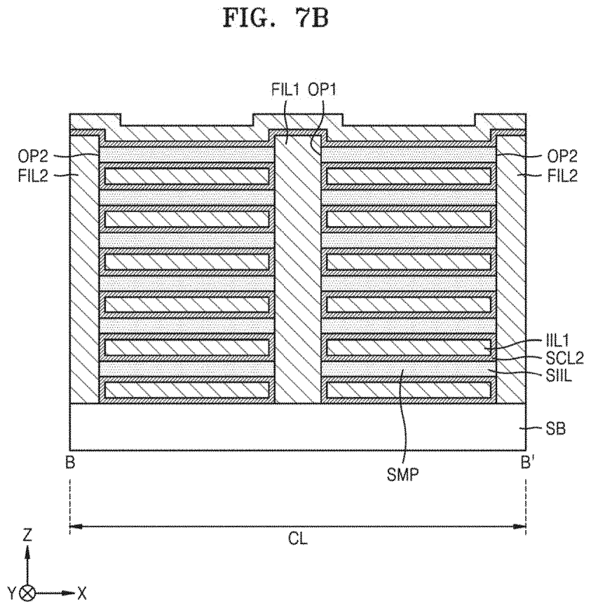

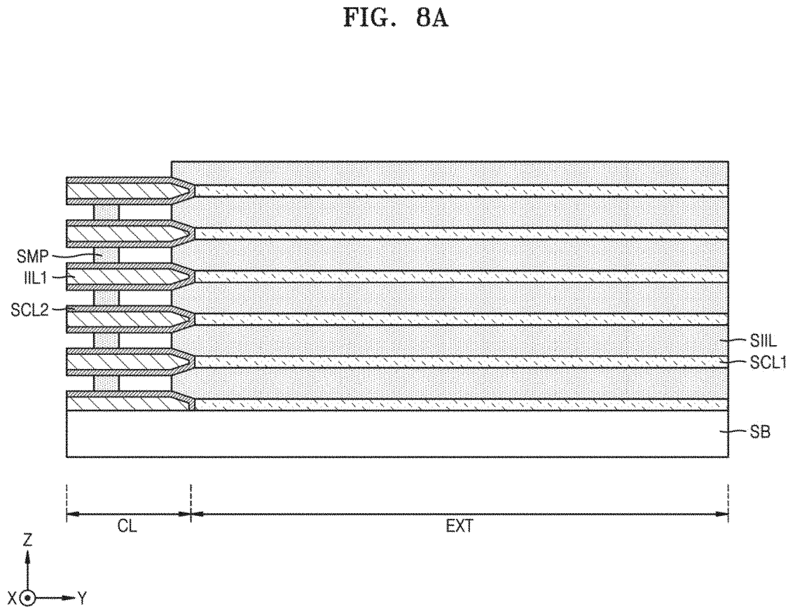

Referring to FIGS. 7A and 7B, second sacrificial layers SCL2 may be formed on the semiconductor layers SIIL of the cell region CL. The interlayer insulating patterns IIL1 may be formed on the second sacrificial layers SCL2.

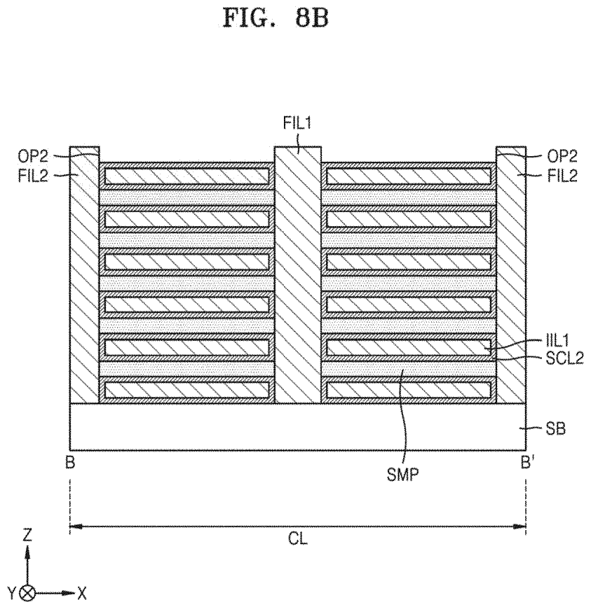

Referring to FIGS. 8A and SB, the semiconductor patterns SMP may be formed from the semiconductor layers SIIL of the cell region CL.

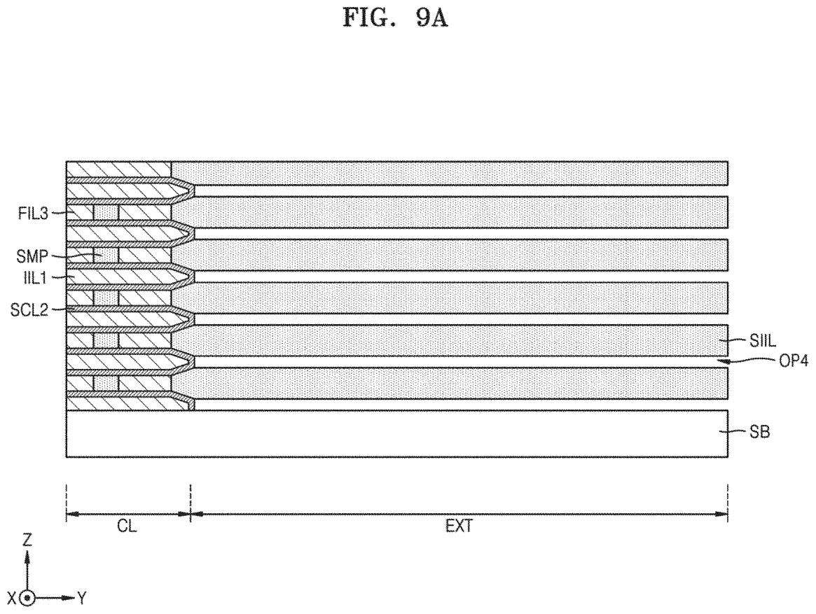

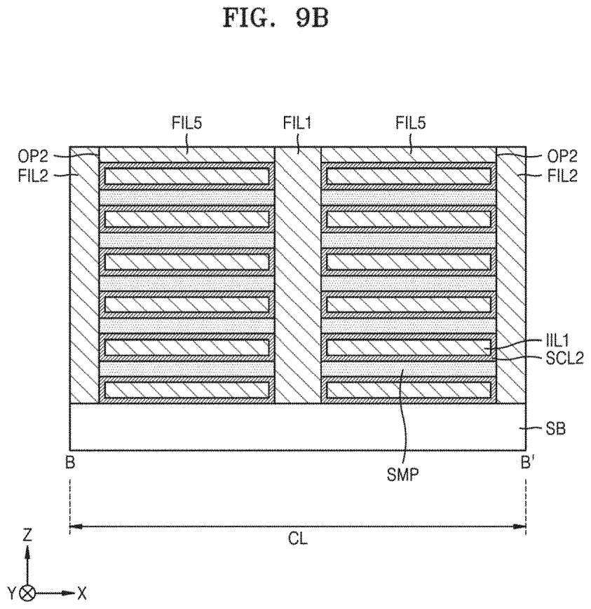

Referring to FIGS. 9A and 9B, the third filling layers FIL3 may fill around the semiconductor patterns SMP. The fifth filling layers FIL5 may be formed on a resultant product. The plurality of first sacrificial layers SCL1 (see FIG. 8A) may be removed. Thus, fourth openings OP4 may be formed between the plurality of semiconductor layers SIIL of the extension region EXT.

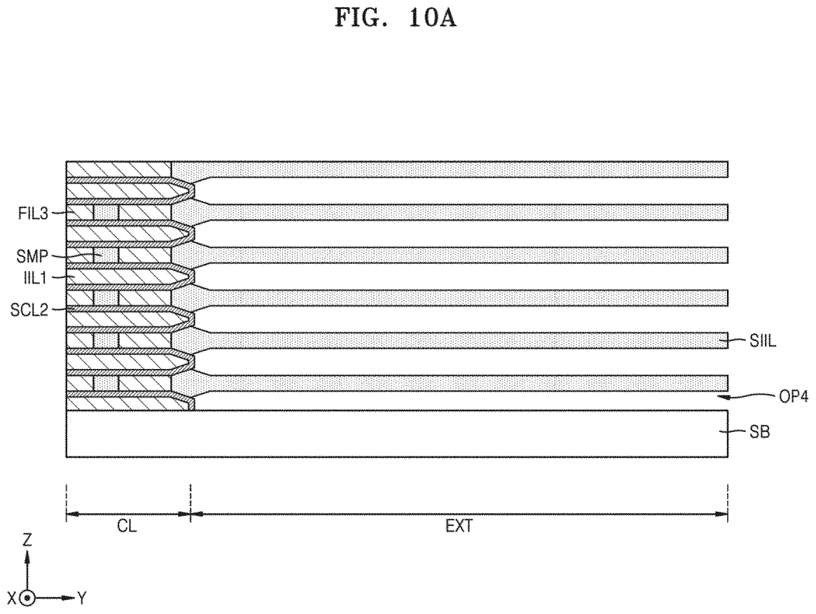

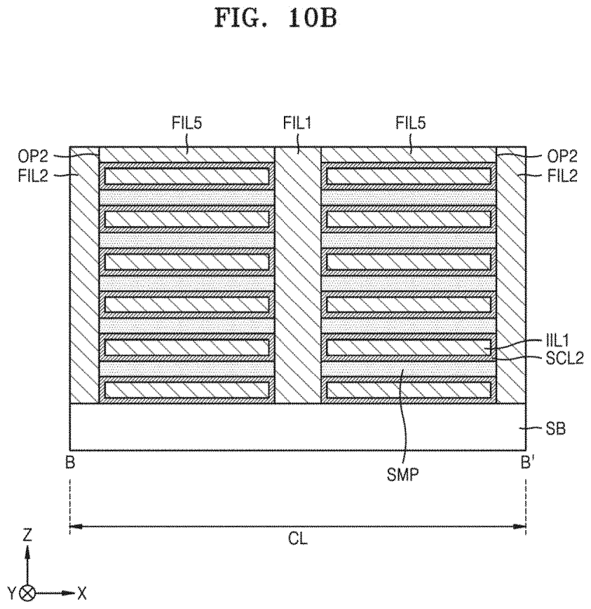

Referring to FIGS. 10A and 10B, the plurality of semiconductor layers SIIL may be thinner in the extension region EXT than in the cell region CL. That is, the fourth openings OP4 may expand.

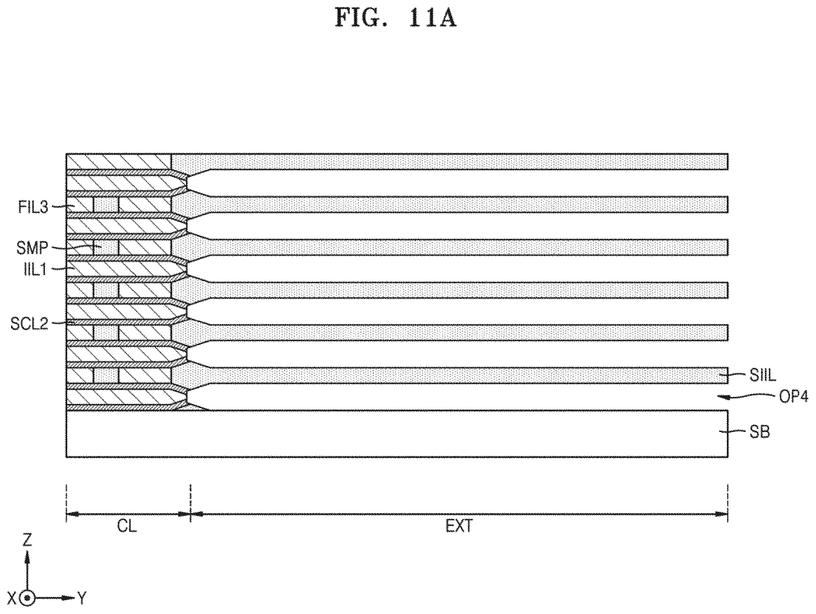

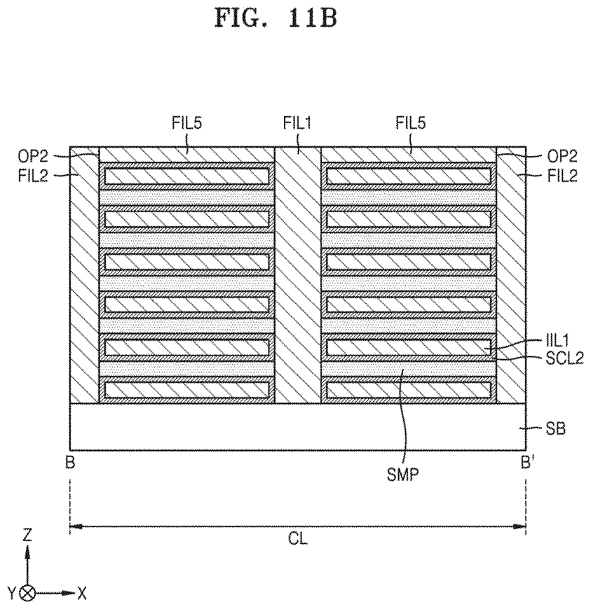

Referring to FIGS. 11A and 11B, the fourth openings OP4 may expand to expose the interlayer insulating patterns IIL1.

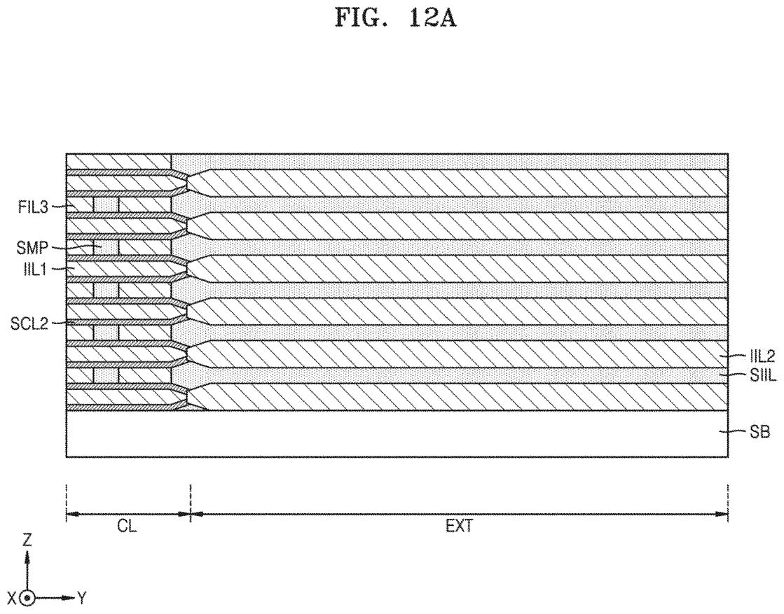

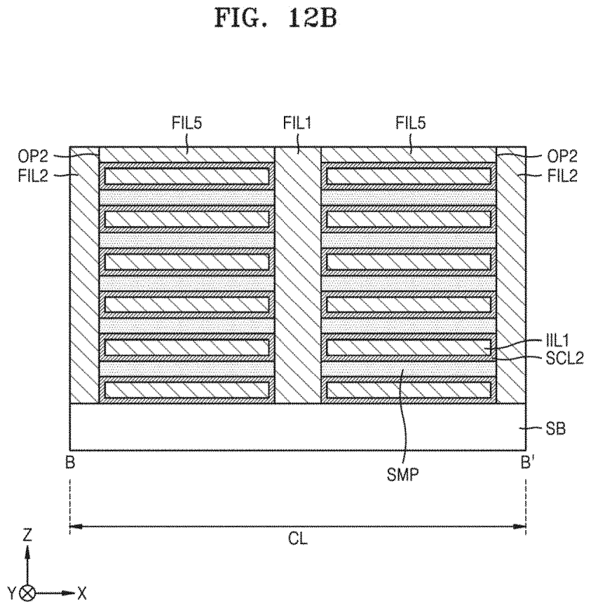

Referring to FIGS. 12A and 12B, the fourth openings OP4 (see FIG. 11A) may be filled with the plurality of interlayer insulating layers IIL2.

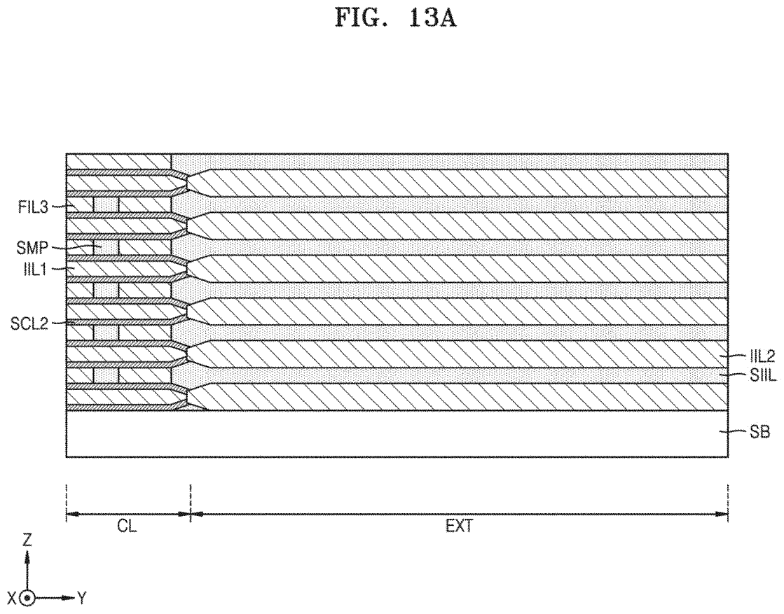

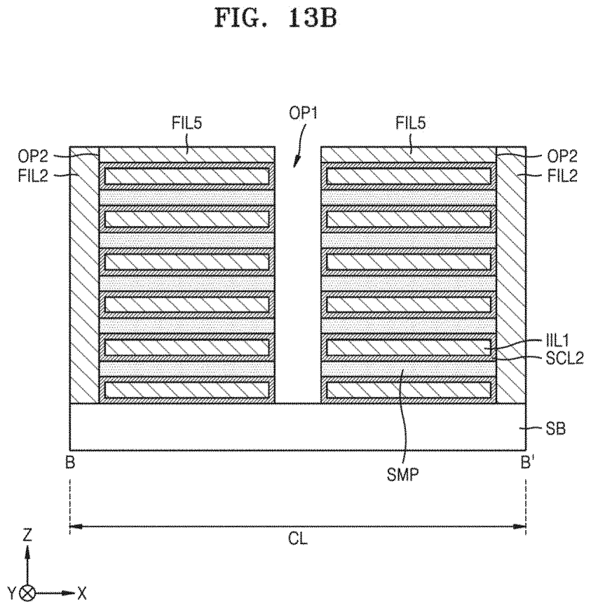

Referring to FIGS. 13A and 13B, the first filling layers FIL1 (see FIG. 12B) in the first opening OP1 may be removed.

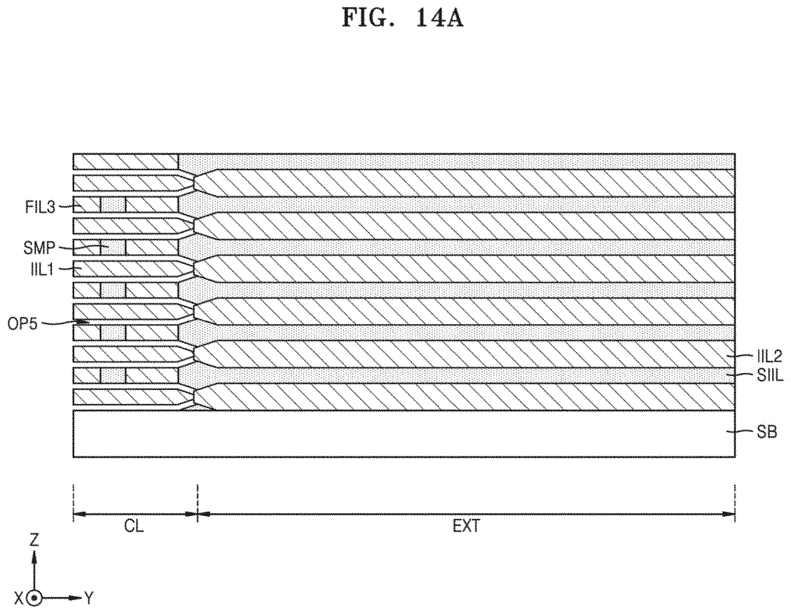

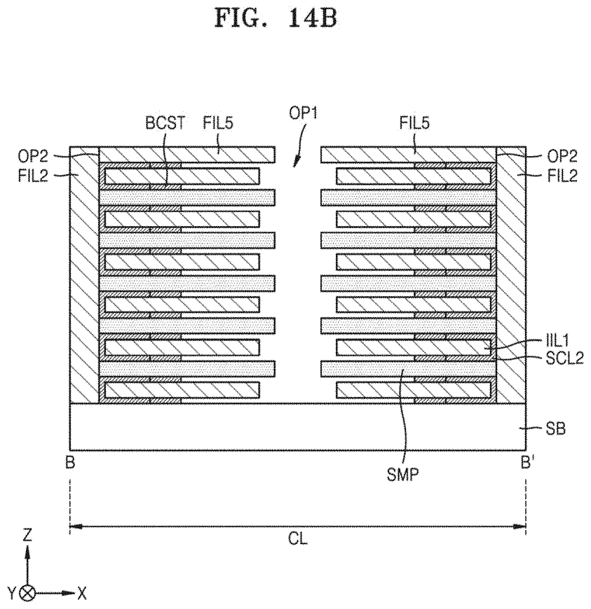

Referring to FIGS. 14A and 14B, the second sacrificial layers SCL2 of the cell region CL may be trimmed to expose upper and lower surfaces of the semiconductor patterns SMP. In addition, second insulating patterns BCST may be formed. The second insulating patterns BCST may be formed by, for example, forming insulating layers on the semiconductor patterns SMP, the interlayer insulating patterns IIL1, and the second sacrificial layers SCL2 and then trimming the insulating layers.

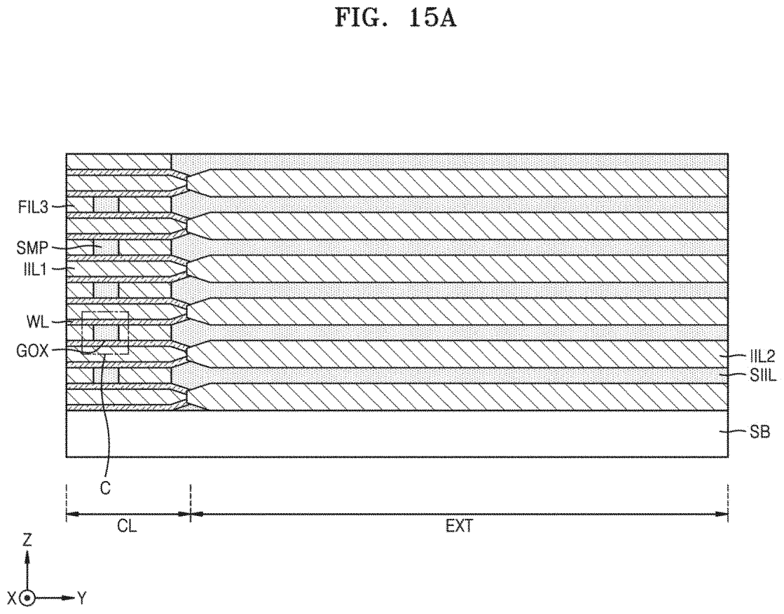

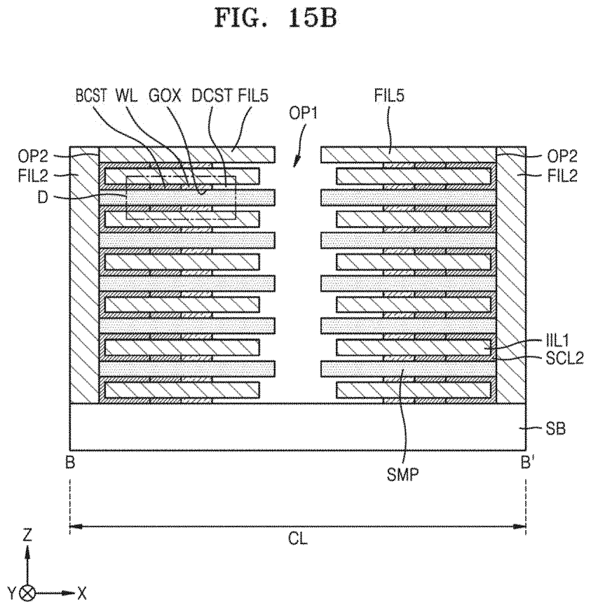

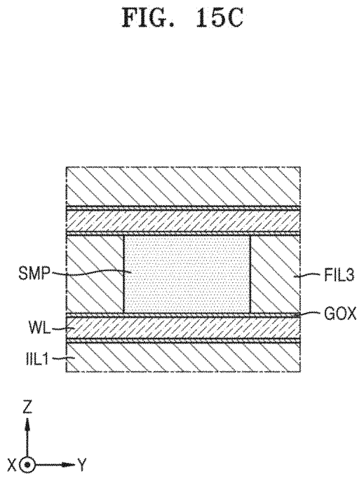

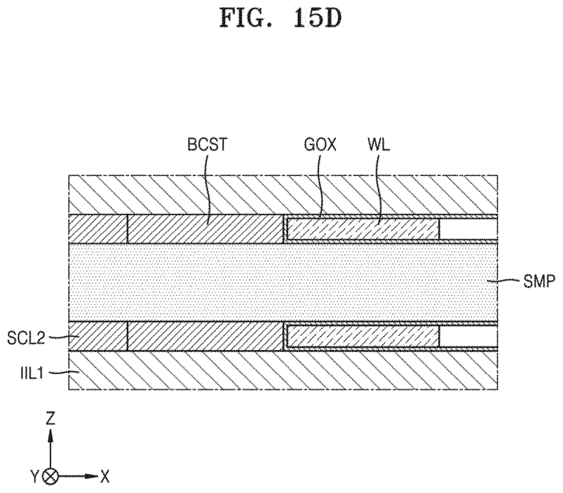

Referring to FIGS. 15A to 15D, the gate dielectric layers GOX may be formed on the semiconductor patterns SMP, the second insulating patterns BCST, and the insulating patterns IIL1. The horizontal conductive lines WL may be formed on the gate dielectric layers GOX. The horizontal conductive lines WL may be formed, for example, by forming conductive layers on the gate dielectric layers GOX and trimming the conductive layers.

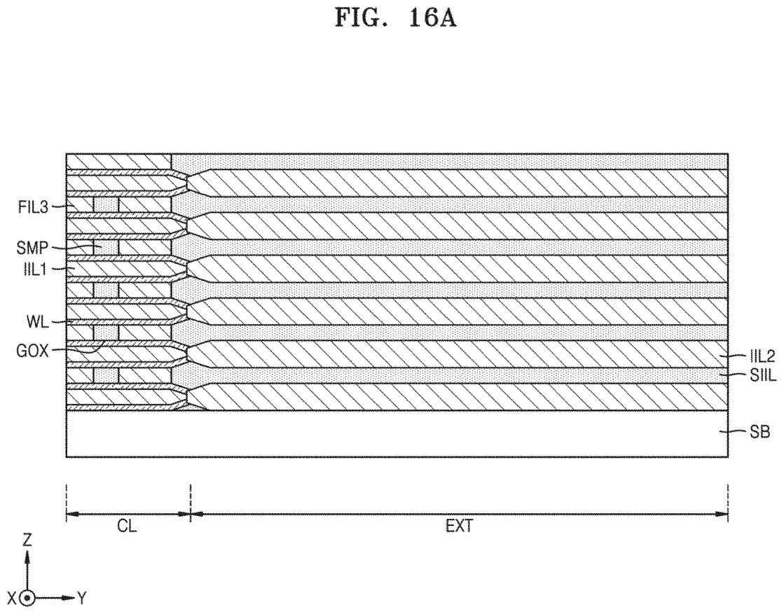

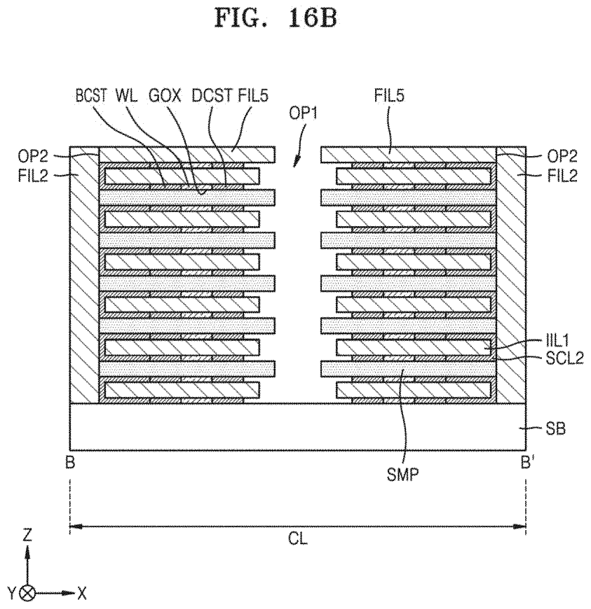

Referring to FIGS. 16A and 16B, the first insulating patterns DCST may be formed. The first insulating patterns DCST may be formed by, for example, forming insulating layers on the gate dielectric layers GOX and trimming the insulating layers.

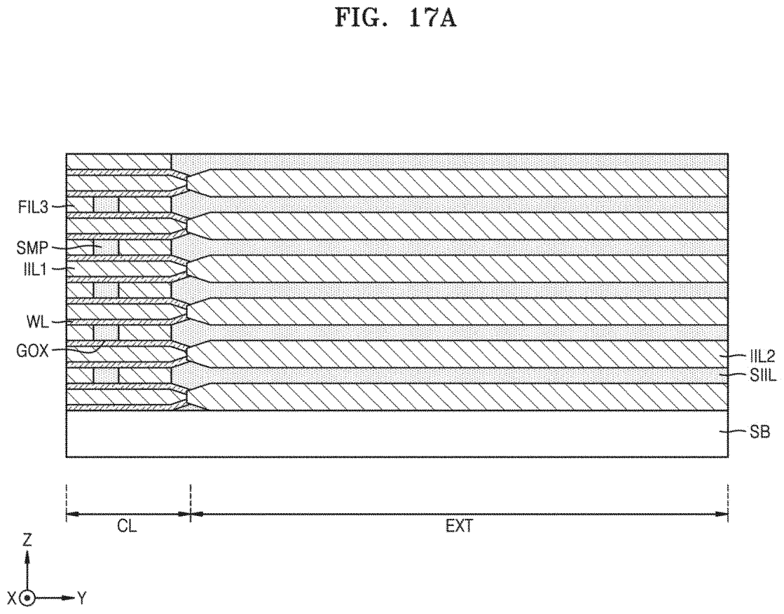

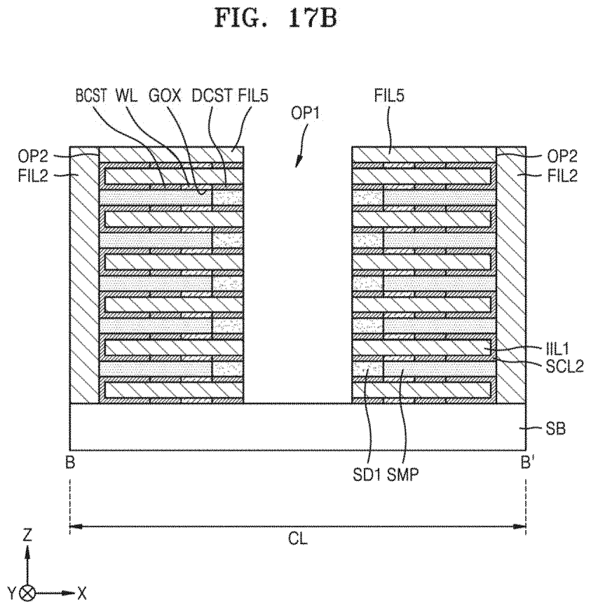

Referring to FIGS. 17A and 17B, protruding portions of the semiconductor patterns SMP may be removed. Also, the first sources/drains SD1 may be formed by doping ends of the semiconductor patterns SMP.

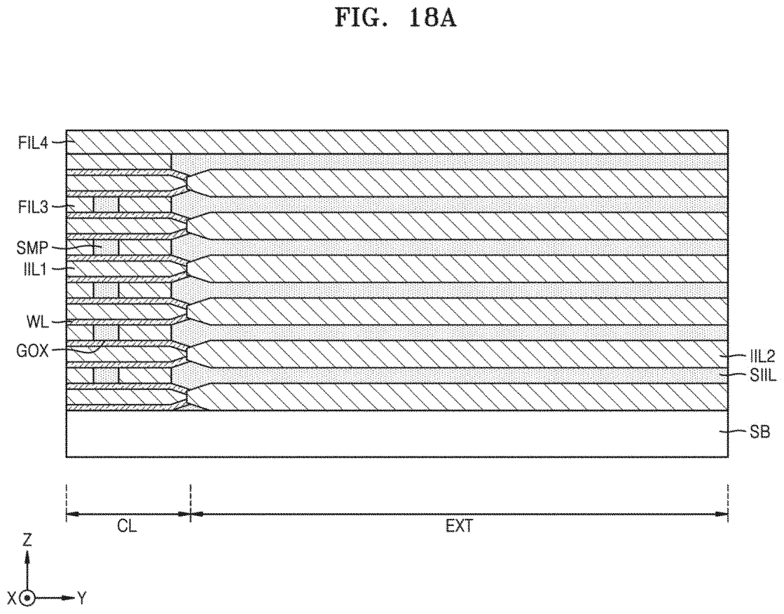

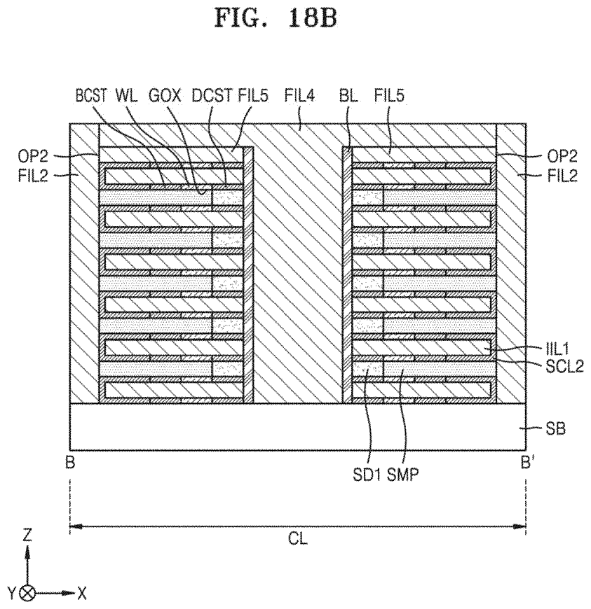

Referring to FIGS. 18A and 18B, vertical conductive lines BL contacting the first sources/drains SD1 and extending in the vertical direction (Z direction) may be formed. Next, the first openings OP1 may be filled with the fourth filling layer FIL4, and the fourth filling layers FIL4 may cover the fifth filling layer FIL5.

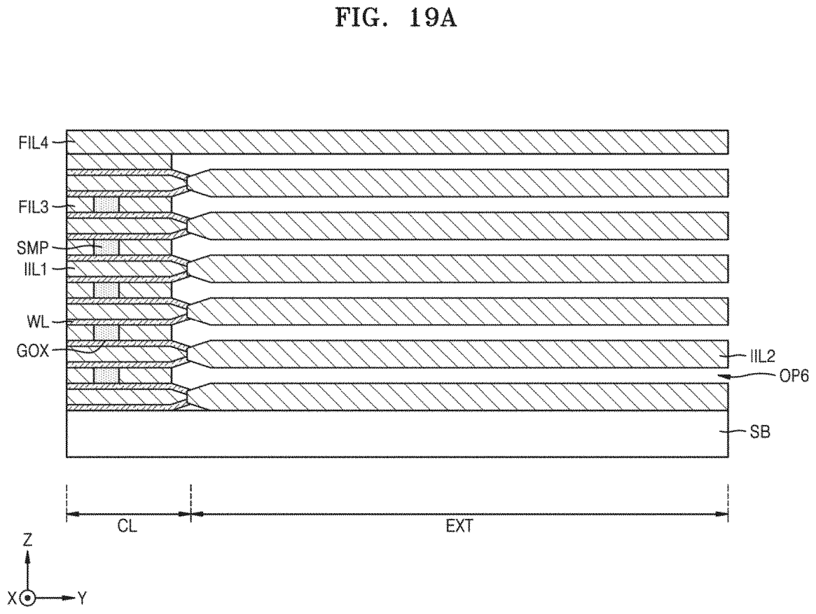

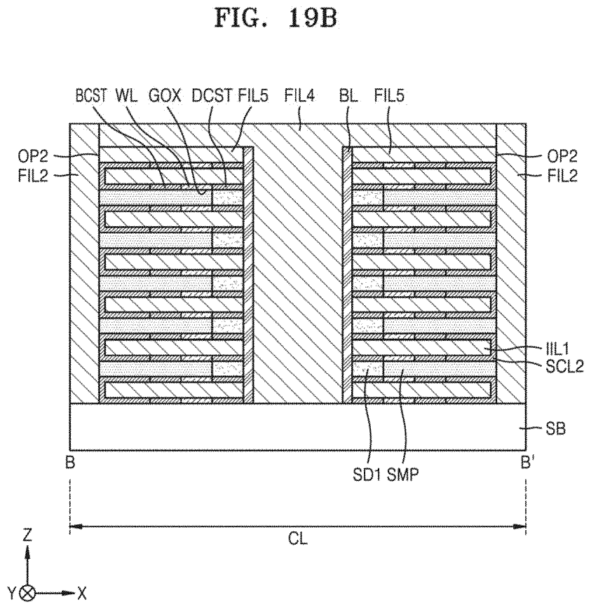

Referring to FIGS. 19A and 19B, the semiconductor layers SIIL (see FIG. 18A) may be removed. Thus, sixth openings OP6 between the plurality of interlayer insulating layers 1112 may be formed.

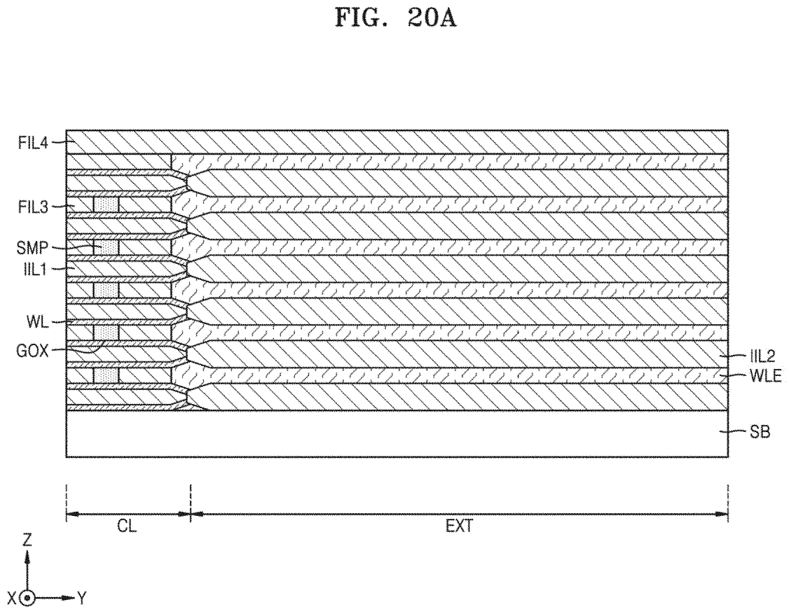

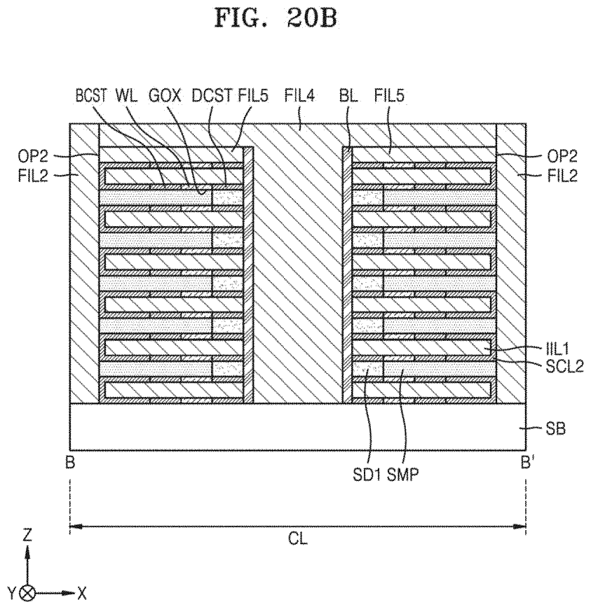

Referring to FIGS. 20A and 20B, the sixth openings OP6 (see FIG. 19A) may be filled with the horizontal conductive line extensions WLE.

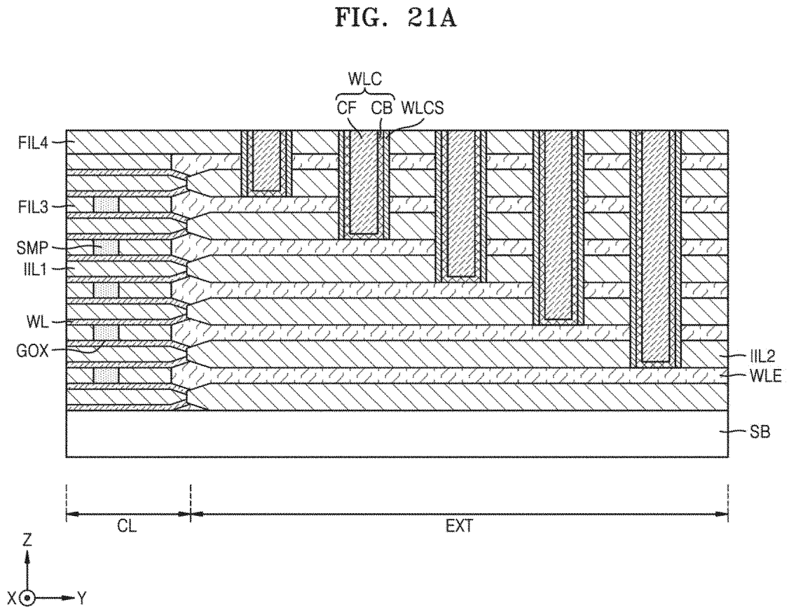

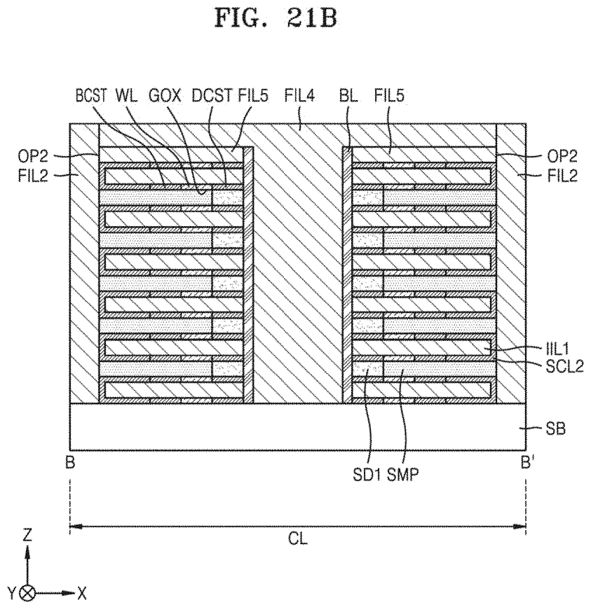

Referring to FIGS. 21A and 21B, the plurality of contacts WLC contacting the plurality of horizontal conductive line extensions WLE, respectively, and the contact spacers WLCS surrounding sidewalls of the plurality of contacts WLC, respectively, may be formed. The plurality of contacts WLC and the plurality of contact spacers WLCS may be manufactured according to the method described with reference to FIGS. 2A to 2K. The first to seventh insulating layers ILa to IILg shown in FIGS. 2A to 2K may correspond to the plurality of interlayer insulating layers IIL2 shown in FIG. 21A, respectively, and the first to sixth material layers MLa to MLf shown in FIGS. 2A to 2K may correspond to the plurality of horizontal conductive line extensions WLE shown in FIG. 21A, respectively. The first to fifth contacts WLC1 to WLC5 shown in FIGS. 2A to 2K may correspond to the plurality of contacts WLC illustrated in FIG. 21A, respectively.

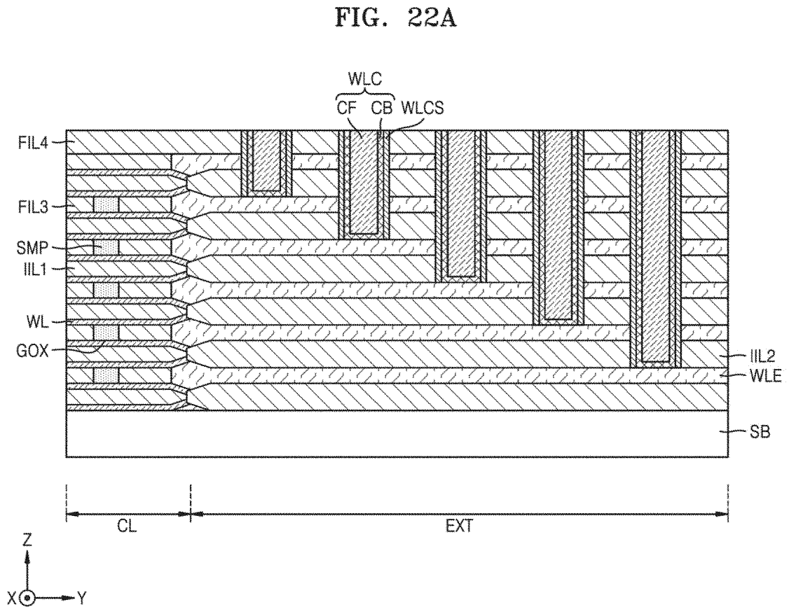

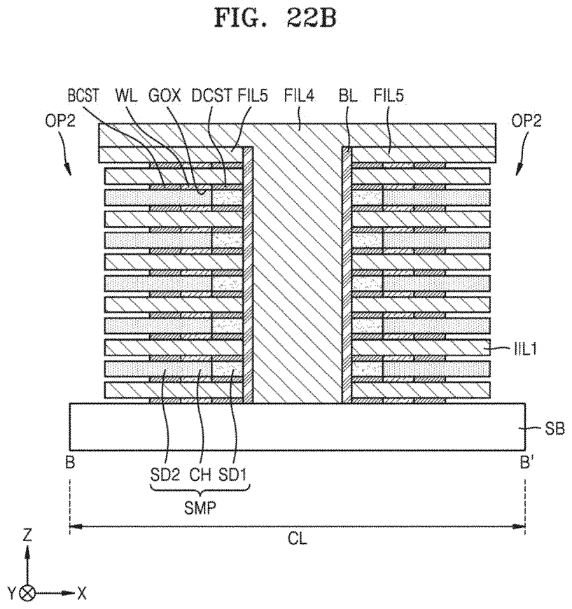

Referring to FIGS. 22A and 22B, the second filling layers FIL2 (see FIG. 21B) in the second opening OP2 may be removed. Also, the second sacrificial layers SCL2 may be removed.

Referring to FIGS. 23A and 23B, the protruding portions of the semiconductor patterns SMP may be removed. Next, the second sources/drains SD2 may be formed by doping the exposed ends of the semiconductor patterns SMP. The semiconductor patterns SMP between the first sources/drains SD1 and the second sources/drains SD2 may be referred to as the channels CH.

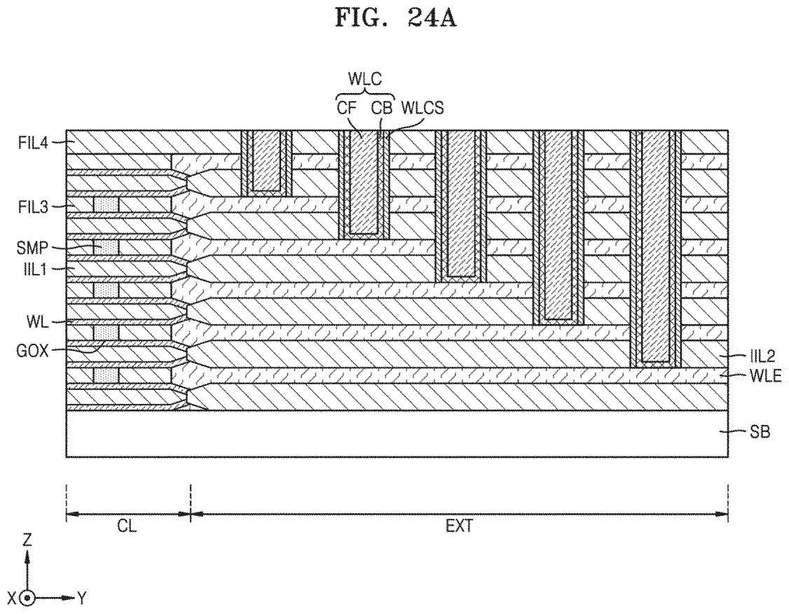

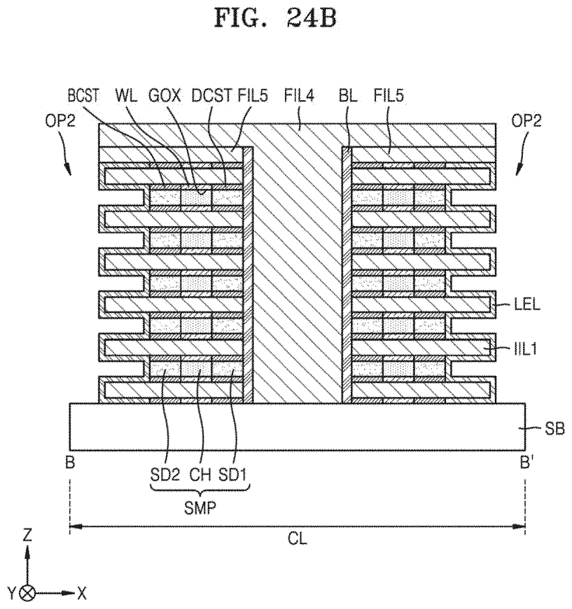

Referring to FIGS. 24A and 24B, lower electrode layers LEL may be formed on the second sources/drains SD2 and the interlayer insulating patterns IIL1.

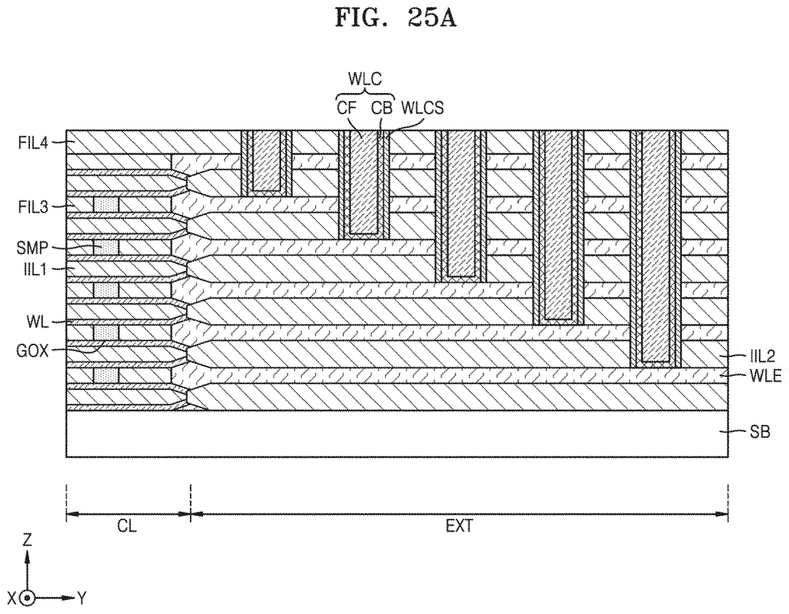

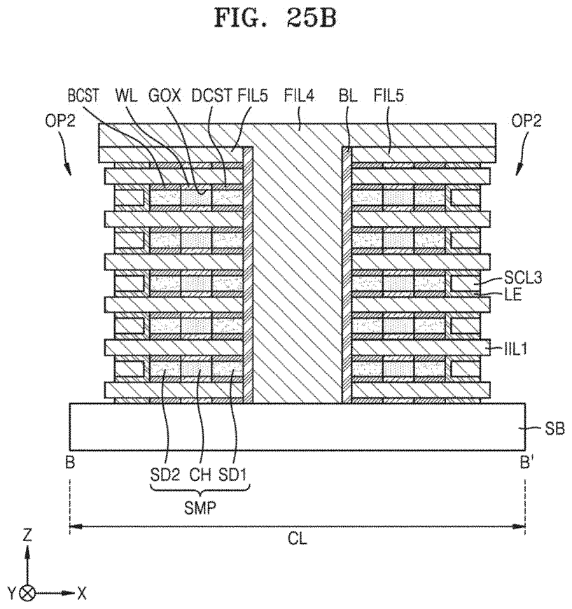

Referring to FIGS. 25A and 25B, third sacrificial layers SCL3 may be formed on the lower electrode layers LIL. Next, by removing protruding portions of the lower electrode layers LEL (see FIG. 24B), the plurality of lower electrodes LE spaced apart from each other may be formed from the lower electrode layers LEL (see FIG. 24B).

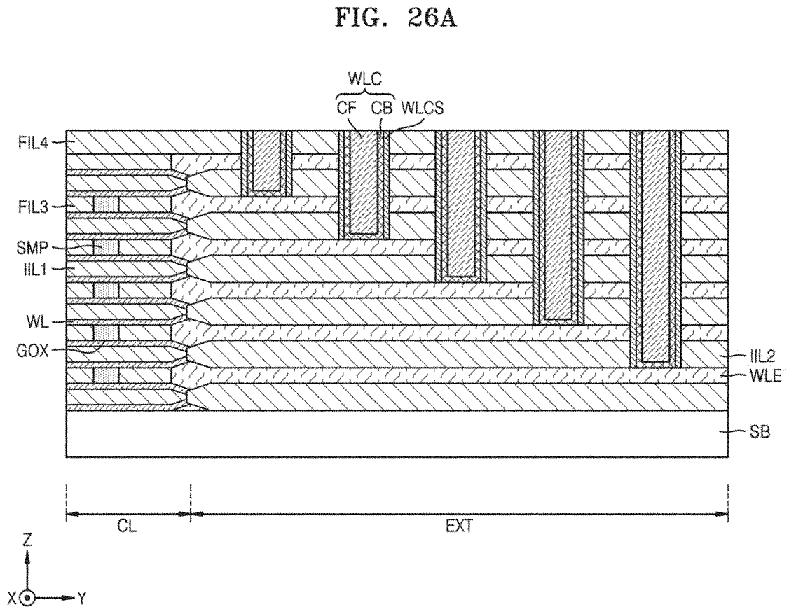

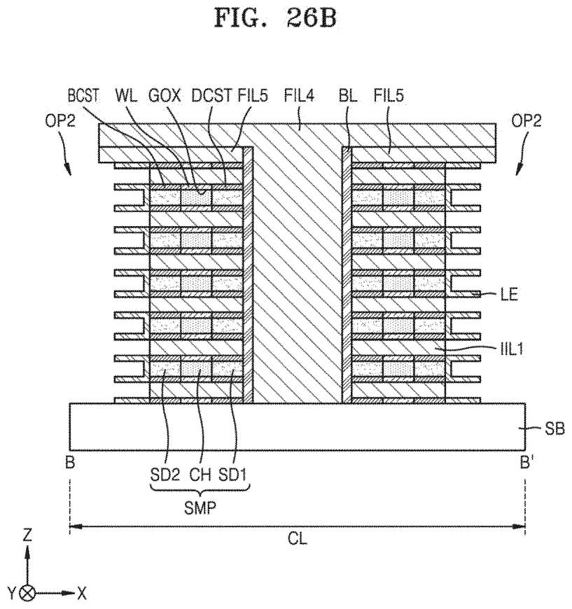

Referring to FIGS. 26A and 26B, the third sacrificial layers SCL3 (see FIG. 25B) may be removed. While the third sacrificial layers SCL3 (see FIG. 25B) are removed, the interlayer insulating patterns IIL1 may be recessed.

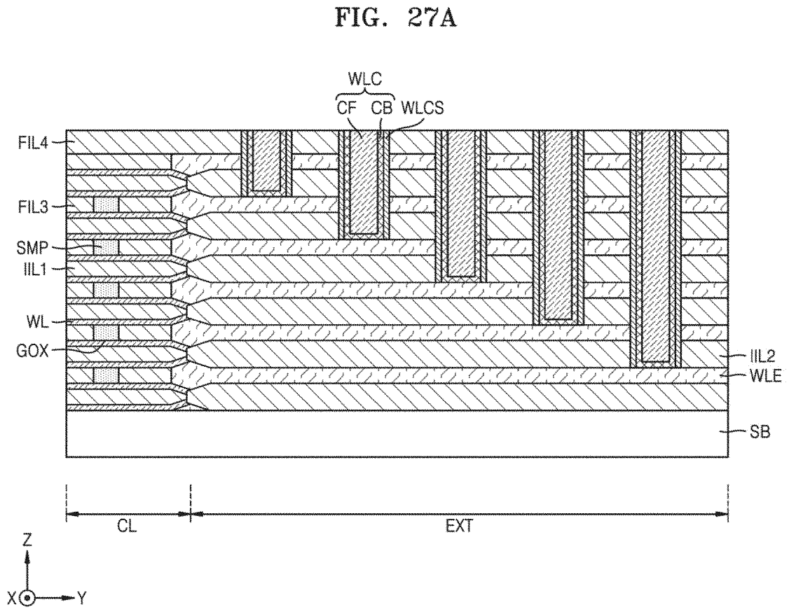

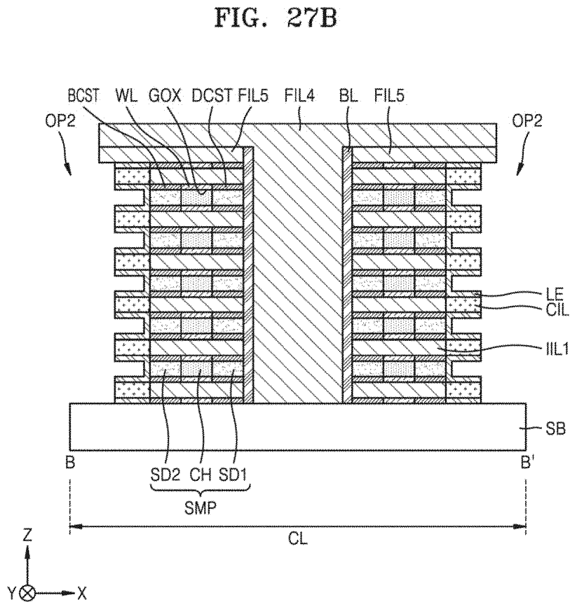

Referring to FIGS. 27A and 27B, the capacitor insulating layers CIL filling between the plurality of lower electrodes LE may be formed.

Referring to FIG. 1C, the capacitor dielectric layer DL may be formed on the lower electrode LE and the capacitor insulating layer CIL. Next, the upper electrode UE may be formed on the capacitor dielectric layer DL. As a result, the semiconductor device SMD may be manufactured.

FIG. 28 is a cross-sectional view illustrating a method of manufacturing a semiconductor device, according to an example embodiment. FIG. 28 corresponds to a cross-sectional view taken along line A-A′ in FIG. 1A.

Referring to FIG. 28, according to the method described with reference to FIGS. 2A to 2K, the plurality of contacts WLC in contact with the plurality of semiconductor layers SIIL, respectively, and the plurality of contact spacers WLCS surrounding the sidewalls of the plurality of contacts WLC, respectively, may be formed. Later, the plurality of semiconductor layers SIIL may be replaced with the plurality of horizontal conductive line extensions WLE, respectively (see FIG. 27A).

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
an extension structure comprising a first horizontal conductive line extension, a first interlayer insulating layer, a second horizontal conductive line extension, and a second interlayer insulating layer that are stacked on a substrate and extending in a first horizontal direction;
a first contact configured to pass through the second interlayer insulating layer, the second horizontal conductive line extension, and the first interlayer insulating layer and contact the first horizontal conductive line extension;
a second contact configured to pass through the second interlayer insulating layer and contact the second horizontal conductive line extension; and
a first contact spacer extending between a sidewall of the first contact and the extension structure and configured to electrically isolate the first contact from the second horizontal conductive line extension.

2. The semiconductor device of claim 1, wherein the first contact comprises:
a first barrier layer on the first horizontal conductive line extension and the first contact spacer; and
a first filling conductive layer on the first barrier layer.

3. The semiconductor device of claim 1 further comprising:
a second contact spacer extending between a sidewall of the second contact and the extension structure.

4. The semiconductor device of claim 3, wherein the second contact comprises:
a second barrier layer on the second horizontal conductive line extension and the second contact spacer; and
a second filling conductive layer on the second barrier layer.

5. The semiconductor device of claim 1, further comprising:
a first upper horizontal conductive line extending in the first horizontal direction from one end of the first horizontal conductive line extension; and
a semiconductor pattern at one side of the first upper horizontal conductive line and extending in a second horizontal direction.

6. The semiconductor device of claim 5, further comprising:
a first lower horizontal conductive line extending parallel to the first upper horizontal conductive line from the one end of the first horizontal conductive line extension,
wherein the semiconductor pattern is between the first upper horizontal conductive line and the first lower horizontal conductive line.

7. The semiconductor device of claim 5, further comprising:
a gate dielectric layer between the first upper horizontal conductive line and the semiconductor pattern.

8. The semiconductor device of claim 5, wherein the semiconductor pattern comprises:
a channel intersecting with the first upper horizontal conductive line in a plan view;
a first source/drain at one end of the channel; and
a second source/drain at an opposite end of the channel.

9. The semiconductor device of claim 8, further comprising:
a vertical conductive line in contact with the first source/drain and extending in a vertical direction.

10. The semiconductor device of claim 8, further comprising:
a capacitor in contact with the second source/drain.

11. The semiconductor device of claim 10, wherein the capacitor comprises a lower electrode contacting the second source/drain, a capacitor dielectric layer on the lower electrode, and an upper electrode on the capacitor dielectric layer.

12. The semiconductor device of claim 8, further comprising:
a second lower horizontal conductive line extending in the first horizontal direction from one end of the second horizontal conductive line extension; and
an interlayer insulating pattern between the first upper horizontal conductive line and the second lower horizontal conductive line.

13. The semiconductor device of claim 12, further comprising:
a first insulating pattern between the interlayer insulating pattern and the first source/drain and being at one side of the first upper horizontal conductive line.

14. The semiconductor device of claim 13, further comprising:
a second insulating pattern between the interlayer insulating pattern and the second source/drain and being on an opposite side of the first upper horizontal conductive line.

15. The semiconductor device of claim 1, wherein the second contact is spaced apart from the first contact in the first horizontal direction.

16. A semiconductor device comprising:
a semiconductor pattern extending in a first horizontal direction, and comprising a first source/drain, a channel, and a second source/drain;
a horizontal conductive line extending in a second horizontal direction and intersecting with the semiconductor pattern in a plan view;
a gate dielectric layer between the horizontal conductive line and the semiconductor pattern;
a capacitor in contact with the second source/drain;
a vertical conductive line in contact with the first source/drain and extending in a vertical direction;
a first horizontal conductive line extension extending from the horizontal conductive line in the second horizontal direction;
a first interlayer insulating layer on the first horizontal conductive line extension;
a second horizontal conductive line extension on the first interlayer insulating layer,
a second interlayer insulating layer on the second horizontal conductive line extension;
a first contact configured to pass through the second interlayer insulating layer, the second horizontal conductive line extension, and the first interlayer insulating layer and contact the first horizontal conductive line extension;
a second contact configured to pass through the second interlayer insulating layer and contact the second horizontal conductive line extension; and
a first contact spacer extending on a sidewall of the first contact configured to electrically isolate the first contact from the second horizontal conductive line extension.

17. A semiconductor device comprising:
a first semiconductor pattern extending in a first horizontal direction, and comprising a first source/drain, a first channel, and a second source/drain;
a second semiconductor pattern extending in the first horizontal direction, spaced apart from the first semiconductor pattern in a vertical direction, and comprising a third source/drain, a second channel, and a fourth source/drain;
a first horizontal conductive line extending in a second horizontal direction and intersecting with the first semiconductor pattern and the second semiconductor pattern in a plan view;
a second horizontal conductive line extending in the second horizontal direction and intersecting with the first semiconductor pattern and the second semiconductor pattern in a plan view;
a gate dielectric layer between the first horizontal conductive line and the first semiconductor pattern and between the second horizontal conductive line and the second semiconductor pattern;
a first capacitor in contact with the second source/drain;
a second capacitor in contact with the fourth source/drain;
a vertical conductive line contacting the first source/drain and the third source/drain and extending in the vertical direction; and
a first horizontal conductive line extension extending from the first horizontal conductive line in the second horizontal direction;
a second horizontal conductive line extension extending from the second horizontal conductive line in the second horizontal direction;
a first interlayer insulating layer between the first horizontal conductive line extension and the second horizontal conductive line extension;
a second interlayer insulating layer on the second horizontal conductive line extension;
a first contact configured to pass through the second interlayer insulating layer, the second horizontal conductive line extension, and the first interlayer insulating layer, and contact the first horizontal conductive line extension;
a second contact configured to pass through the second interlayer insulating layer and contact the second horizontal conductive line extension; and
a first contact spacer extending on a sidewall of the first contact configured to electrically isolate the first contact from the second horizontal conductive line extension.

18. The semiconductor device of claim 17, wherein
the first capacitor comprises a first lower electrode, a first capacitor dielectric layer, and a first upper electrode, and
the second capacitor comprises a second lower electrode, a second capacitor dielectric layer, and a second upper electrode.

19. The semiconductor device of claim 18, wherein the first capacitor dielectric layer is integral with the second capacitor dielectric layer.

20. The semiconductor device of claim 18, wherein the first upper electrode is integral with the second upper electrode.
